(19) United States
(12) Patent Application Publication
(10) Pub. No.: US 2026/0188240 A1
(43) Pub. Date: Jul. 2, 2026

(54) SHIFT REGISTER AND DRIVE METHOD THEREFOR, AND GATE DRIVE CIRCUIT AND DISPLAY APPARATUS

(71) Applicants: Hefei Xinsheng Optoelectronics Technology Co., Ltd., Hefei, Anhui (CN); BOE Technology Group Co., Ltd., Beijing (CN)

(72) Inventors: Tingting ZHAO, Beijing (CN); Tong YANG, Beijing (CN); Peng WU, Beijing (CN); Miao ZHANG, Beijing (CN); Youlu LI, Beijing (CN); Xiong XIONG, Beijing (CN); Ran ZHANG, Beijing (CN); Yongcan WANG, Beijing (CN)

(21) Appl. No.: 19/130,554

(22) PCT Filed: Jun. 19, 2024
(86) PCT No.: PCT/CN2024/100114

§ 371 Date: May 16, 2025

(30) Foreign Application Priority Data
Jul. 20, 2023 (CN) 202310904148.7

(51) Int. Cl. G09G 3/3266; G09G 3/36; G11C 19/28

(52) U.S. Cl. CPC G09G 3/3266; G09G 3/3677; G11C 19/28; G09G 2300/0408; G09G 2310/0286; G09G 2330/021

(57) ABSTRACT

Disclosed is a shift register including: an input sub-circuit, an output sub-circuit and a first control sub-circuit, wherein the input sub-circuit is electrically connected to a signal input end and a pull-up node, and is configured to provide a signal to the pull-up node under the control of a signal from the signal input end; the output sub-circuit is electrically connected to a first output end, the pull-up node and a clock signal end, and is configured to provide a signal from the clock signal end to the first output end under the control of a signal from the pull-up node; and the first control sub-circuit is electrically connected to a control signal end and a signal input end, and is configured to provide a signal from the control signal end to the signal input end under the control of the signal from the control signal end.

### CROSS-REFERENCE TO RELATED APPLICATIONS

The present application is a U.S. National Phase Entry of International Application No. PCT/CN2024/100114 having an international filing date of Jun. 19, 2024, which claims priority to Chinese patent application No. 202310904148.7, filed to the CNIPA on Jul. 20, 2023, and entitled “Shift Register and Drive Method Therefor, and Gate Drive Circuit and Display Apparatus”, contents of the above-identified applications should be construed as being hereby incorporated into the present application by reference.

### TECHNICAL FIELD

The present disclosure relates, but is not limited, to the field of display technologies, and in particular to a shift register and a drive method therefor, a gate drive circuit, and a display apparatus.

### BACKGROUND

In recent years, flat panel displays, such as Thin Film Transistor-Liquid Crystal Displays (TFT-LCDs) and Active Matrix Organic Light Emitting Diodes (AMOLEDs), have been widely used in TV, mobile phones, and other electronic products because of their light weight, small thickness, and low power consumption.

With progress of science and technology, display panels with high resolution and narrow bezels have become a development trend. Therefore, a Gate Driver on Array (GOA) technology has emerged. The GOA technology refers to a technology of arranging GOA circuits used for driving gate lines on both sides of an effective display region of an array substrate in a display panel.

### SUMMARY

The following is a summary of subject matters described in the present disclosure in detail. This summary is not intended to limit the protection scope of claims.

In a first aspect, the present disclosure provides a shift register including an input sub-circuit, an output sub-circuit, and a first control sub-circuit. A working process of the shift register includes a display phase and a non-display phase, and the display phase includes an output phase and a non-output phase.

The input sub-circuit is electrically connected with a signal input terminal and a pull-up node, respectively, and is configured to provide a signal to the pull-up node under control of a signal of the signal input terminal.

The output sub-circuit is electrically connected with a first output terminal, the pull-up node, and a clock signal terminal, respectively, and is configured to provide a signal of the clock signal terminal to the first output terminal under control of a signal of the pull-up node.

The first control sub-circuit is electrically connected with a control signal terminal and the signal input terminal, and is configured to provide a signal of the control signal terminal to the signal input terminal under control of the signal of the control signal terminal.

In an exemplary implementation mode, the shift register further includes a first reset sub-circuit.

The first reset sub-circuit is electrically connected with a total reset signal terminal, the pull-up node, and a first power supply terminal, respectively, and is configured to provide a signal of the first power supply terminal to the pull-up node under control of the total reset signal terminal.

The total reset signal terminal has an active level signal in part of time periods of the non-display phase and an inactive level signal in the display phase.

In an exemplary implementation mode, the control signal terminal includes at least one of a first control signal terminal and a second control signal terminal.

The first control signal terminal is electrically connected with a total reset signal terminal, and the second control signal terminal is electrically connected with the first output terminal.

In an exemplary implementation mode, in a state in which the control signal terminal includes the first control signal terminal, the first control sub-circuit includes a nineteenth transistor.

A control electrode and a first electrode of the nineteenth transistor are respectively electrically connected with the first control signal terminal, and a second electrode of the nineteenth transistor is electrically connected with the signal input terminal.

In an exemplary implementation mode, in a state in which the control signal terminal includes the second control signal terminal, the first control sub-circuit includes a twentieth transistor.

A control electrode and a first electrode of the twentieth transistor are respectively electrically connected with a second control signal terminal, and a second electrode of the twentieth transistor is electrically connected with the signal input terminal.

In an exemplary implementation mode, in a state in which the control signal terminal includes the first control signal terminal and the second control signal terminal, the control sub-circuit includes a nineteenth transistor and a twentieth transistor.

A control electrode and a first electrode of the nineteenth transistor are respectively electrically connected with the first control signal terminal, and a second electrode of the nineteenth transistor is electrically connected with the signal input terminal.

A control electrode and a first electrode of the twentieth transistor are respectively electrically connected with the second control signal terminal, and a second electrode of the twentieth transistor is electrically connected with the signal input terminal.

In an exemplary implementation mode, the input sub-circuit includes a first transistor.

A control electrode of the first transistor is electrically connected with the signal input terminal, a first electrode of the first transistor is electrically connected with the signal input terminal or a second power supply terminal, and a second electrode of the first transistor is electrically connected with the pull-up node.

In an exemplary implementation mode, the input sub-circuit includes a first transistor and a twenty-first transistor.

A control electrode of the first transistor is electrically connected with the signal input terminal, a first electrode of the first transistor is electrically connected with the signal input terminal or a second power supply terminal, and a second electrode of the first transistor is electrically connected with the control node.

A control electrode and a first electrode of the twenty-first transistor are respectively electrically connected with the control node, and a second electrode of the twenty-first transistor is electrically connected with the pull-up node.

In an exemplary implementation mode, the output sub-circuit includes a twelfth transistor and a capacitor.

A control electrode of the second transistor is electrically connected with the pull-up node, a first electrode of the second transistor is electrically connected with the clock signal terminal, and a second electrode of the second transistor is electrically connected with the first output terminal.

A first terminal of the capacitor is electrically connected with the pull-up node, and a second terminal of the capacitor is electrically connected with the first output terminal.

In an exemplary implementation mode, the output sub-circuit is further electrically connected with a second output terminal, and is configured to provide a signal of the clock signal terminal to the second output terminal under control of the signal of the pull-up node.

In an exemplary implementation mode, the output sub-circuit includes a second transistor, a third transistor, and a capacitor.

A control electrode of the second transistor is electrically connected with the pull-up node, a first electrode of the second transistor is electrically connected with the clock signal terminal, and a second electrode of the second transistor is electrically connected with the first output terminal.

A control electrode of the third transistor is electrically connected with the pull-up node, a first electrode of the third transistor is electrically connected with the clock signal terminal, and a second electrode of the third transistor is electrically connected with a second output terminal.

A first terminal of the capacitor is electrically connected with the pull-up node, and a second terminal of the capacitor is electrically connected with the first output terminal.

In an exemplary implementation mode, the first reset sub-circuit includes a fourth transistor.

A control electrode of the fourth transistor is electrically connected with the total reset signal terminal, a first electrode of the fourth transistor is electrically connected with the pull-up node, and a second electrode of the fourth transistor is electrically connected with the first power supply terminal.

In an exemplary implementation mode, the shift register further includes a second reset sub-circuit.

The second reset sub-circuit is electrically connected with a first reset signal terminal, a second reset signal terminal, the pull-up node, the first output terminal, a first power supply terminal, and a third power supply terminal, respectively, and is configured to provide a signal of the first power supply terminal to the pull-up node and provide a signal of the third power supply terminal to the first output terminal under control of signals of the first reset signal terminal and the second reset signal terminal.

An absolute value of a voltage of the signal of the first power supply terminal is greater than an absolute value of a voltage of the signal of the third power supply terminal.

The first reset signal terminal and the second reset signal terminal have inactive level signals in the non-display phase and the output phase, and have active level signals in part of time periods of the non-output phase.

In an exemplary implementation mode, the second reset sub-circuit includes a fifth transistor and a sixth transistor.

A control electrode of the fifth transistor is electrically connected with a first reset signal terminal, a first electrode of the fifth transistor is electrically connected with the pull-up node, and a second electrode of the fifth transistor is electrically connected with the first power supply terminal.

A control electrode of the sixth transistor is electrically connected with the second reset signal terminal, a first electrode of the sixth transistor is electrically connected with the first output terminal, and a second electrode of the sixth transistor is electrically connected with the third power supply terminal.

In an exemplary implementation mode, the shift register further includes a noise reduction sub-circuit, and the noise reduction sub-circuit includes at least one of a first noise reduction sub-circuit and a second noise reduction sub-circuit.

The first noise reduction sub-circuit is electrically connected with a fourth power supply terminal, the signal input terminal, the pull-up node, the first output terminal, the second output terminal, a first power supply terminal, and a third power supply terminal, respectively, and is configured to provide a signal of the first power supply terminal to the pull-up node and the second output terminal and provide a signal of the third power supply terminal to a pull-down node under control of signals of the signal input terminal, the pull-up node, and the fourth power supply terminal.

The second noise reduction sub-circuit is electrically connected with a fifth power supply terminal, the signal input terminal, the pull-up node, the first output terminal, the second output terminal, the first power supply terminal, and the third power supply terminal, respectively, and is configured to provide the signal of the first power supply terminal to the pull-up node and the second output terminal and provide the signal of the third power supply terminal to the pull-down node under control of signals of the signal input terminal, the pull-up node, and the fifth power supply terminal.

In an exemplary implementation mode, the first noise reduction sub-circuit includes a seventh transistor, an eighth transistor, a ninth transistor, a thirteenth transistor, a fourteenth transistor, and a fifteenth transistor, and the second noise reduction sub-circuit includes a tenth transistor, an eleventh transistor, a twelfth transistor, a sixteenth transistor, a seventeenth transistor, and an eighteenth transistor.

A control electrode of the seventh transistor is electrically connected with the signal input terminal, a first electrode of the seventh transistor is electrically connected with a first pull-down node, and a second electrode of the seventh transistor is electrically connected with the first power supply terminal.

A control electrode of the eighth transistor is electrically connected with the pull-up node, a first electrode of the eighth transistor is electrically connected with the first pull-down node, and a second electrode of the eighth transistor is electrically connected with the first power supply terminal.

A control electrode and a first electrode of the ninth transistor are respectively electrically connected with a fourth power supply terminal, and a second electrode of the ninth transistor is electrically connected with the first pull-down node.

A control electrode of the tenth transistor is electrically connected with the signal input terminal, a first electrode of the tenth transistor is electrically connected with a second pull-down node, and a second electrode of the tenth transistor is electrically connected with the first power supply terminal.

A control electrode of the eleventh transistor is electrically connected with the pull-up node, a first electrode of the eleventh transistor is electrically connected with the second pull-down node, and a second electrode of the eleventh transistor is electrically connected with the first power supply terminal.

A control electrode and a first electrode of the twelfth transistor are respectively electrically connected with a fifth power supply terminal, and a second electrode of the twelfth transistor is electrically connected with the second pull-down node.

A control electrode of the thirteenth transistor is electrically connected with the first pull-down node, a first electrode of the thirteenth transistor is electrically connected with the pull-up node, and a second electrode of the thirteenth transistor is electrically connected with the first power supply terminal.

A control electrode of the fourteenth transistor is electrically connected with the first pull-down node, a first electrode of the fourteenth transistor is electrically connected with the first output terminal, and a second electrode of the fourteenth transistor is electrically connected with a third power supply terminal.

A control electrode of the fifteenth transistor is electrically connected with the first pull-down node, a first electrode of the fifteenth transistor is electrically connected with the second output terminal, and a second electrode of the fifteenth transistor is electrically connected with the first power supply terminal.

A control electrode of the sixteenth transistor is electrically connected with the second pull-down node, a first electrode of the sixteenth transistor is electrically connected with the pull-up node, and a second electrode of the sixteenth transistor is electrically connected with the first power supply terminal.

A control electrode of the seventeenth transistor is electrically connected with the second pull-down node, a first electrode of the seventeenth transistor is electrically connected with the first output terminal, and a second electrode of the seventeenth transistor is electrically connected with the third power supply terminal.

A control electrode of the eighteenth transistor is electrically connected with the second pull-down node, a first electrode of the eighteenth transistor is electrically connected with the second output terminal, and a second electrode of the eighteenth transistor is electrically connected with the first power supply terminal.

In an exemplary implementation mode, the shift register further includes a first reset sub-circuit, a second reset sub-circuit, and a noise reduction sub-circuit; wherein the input sub-circuit includes a first transistor, the output sub-circuit includes a second transistor, a third transistor, and a capacitor, the first control sub-circuit includes at least one of a nineteenth transistor and a twentieth transistor; the first reset sub-circuit includes a fourth transistor, the second reset sub-circuit includes a fifth transistor and a sixth transistor, and the noise reduction sub-circuit includes a seventh transistor to an eighteenth transistor.

A control electrode of the first transistor is electrically connected with the signal input terminal, a first electrode of the first transistor is electrically connected with the signal input terminal or a second power supply terminal, and a second electrode of the first transistor is electrically connected with the pull-up node.

A control electrode of the second transistor is electrically connected with the pull-up node, a first electrode of the second transistor is electrically connected with the clock signal terminal, and a second electrode of the second transistor is electrically connected with the first output terminal.

A control electrode of the third transistor is electrically connected with the pull-up node, a first electrode of the third transistor is electrically connected with the clock signal terminal, and a second electrode of the third transistor is electrically connected with a second output terminal.

A first terminal of the capacitor is electrically connected with the pull-up node, and a second terminal of the capacitor is electrically connected with the first output terminal.

A control electrode of the fourth transistor is electrically connected with a total reset signal terminal, a first electrode of the fourth transistor is electrically connected with the pull-up node, and a second electrode of the fourth transistor is electrically connected with a first power supply terminal.

A control electrode of the fifth transistor is electrically connected with a first reset signal terminal, a first electrode of the fifth transistor is electrically connected with the pull-up node, and a second electrode of the fifth transistor is electrically connected with the first power supply terminal.

A control electrode of the sixth transistor is electrically connected with a second reset signal terminal, a first electrode of the sixth transistor is electrically connected with the first output terminal, and a second electrode of the sixth transistor is electrically connected with the first power supply terminal.

A control electrode of the seventh transistor is electrically connected with the signal input terminal, a first electrode of the seventh transistor is electrically connected with a first pull-down node, and a second electrode of the seventh transistor is electrically connected with the first power supply terminal.

A control electrode of the eighth transistor is electrically connected with the pull-up node, a first electrode of the eighth transistor is electrically connected with the first pull-down node, and a second electrode of the eighth transistor is electrically connected with the first power supply terminal.

A control electrode and a first electrode of the ninth transistor are respectively electrically connected with a fourth power supply terminal, and a second electrode of the ninth transistor is electrically connected with the first pull-down node.

A control electrode of the tenth transistor is electrically connected with the signal input terminal, a first electrode of the tenth transistor is electrically connected with a second pull-down node, and a second electrode of the tenth transistor is electrically connected with the first power supply terminal.

A control electrode of the eleventh transistor is electrically connected with the pull-up node, a first electrode of the eleventh transistor is electrically connected with the second pull-down node, and a second electrode of the eleventh transistor is electrically connected with the first power supply terminal.

A control electrode and a first electrode of the twelfth transistor are respectively electrically connected with a fifth power supply terminal, and a second electrode of the twelfth transistor is electrically connected with the second pull-down node.

A control electrode of the thirteenth transistor is electrically connected with the first pull-down node, a first electrode of the thirteenth transistor is electrically connected with the pull-up node, and a second electrode of the thirteenth transistor is electrically connected with the first power supply terminal.

A control electrode of the fourteenth transistor is electrically connected with the first pull-down node, a first electrode of the fourteenth transistor is electrically connected with the first output terminal, and a second electrode of the fourteenth transistor is electrically connected with a third power supply terminal.

A control electrode of the fifteenth transistor is electrically connected with the first pull-down node, a first electrode of the fifteenth transistor is electrically connected with the second output terminal, and a second electrode of the fifteenth transistor is electrically connected with the first power supply terminal.

A control electrode of the sixteenth transistor is electrically connected with the second pull-down node, a first electrode of the sixteenth transistor is electrically connected with the pull-up node, and a second electrode of the sixteenth transistor is electrically connected with the first power supply terminal.

A control electrode of the seventeenth transistor is electrically connected with the second pull-down node, a first electrode of the seventeenth transistor is electrically connected with the first output terminal, and a second electrode of the seventeenth transistor is electrically connected with the third power supply terminal.

A control electrode of the eighteenth transistor is electrically connected with the second pull-down node, a first electrode of the eighteenth transistor is electrically connected with the second output terminal, and a second electrode of the eighteenth transistor is electrically connected with the first power supply terminal.

A control electrode and a first electrode of the nineteenth transistor are respectively electrically connected with a first control signal terminal, and a second electrode of the nineteenth transistor is electrically connected with the signal input terminal.

A control electrode and a first electrode of the twentieth transistor are respectively electrically connected with a second control signal terminal, and a second electrode of the twentieth transistor is electrically connected with the signal input terminal.

In an exemplary implementation mode, the shift register further includes a first reset sub-circuit, a second reset sub-circuit, and a noise reduction sub-circuit; wherein the input sub-circuit includes a first transistor and a twenty-first transistor, the output sub-circuit includes a second transistor, a third transistor, and a capacitor, the first control sub-circuit includes at least one of a nineteenth transistor and a twentieth transistor; the first reset sub-circuit includes a fourth transistor, the second reset sub-circuit includes a fifth transistor and a sixth transistor, and the noise reduction sub-circuit includes a seventh transistor to an eighteenth transistor.

A control electrode of the first transistor is electrically connected with the signal input terminal, a first electrode of the first transistor is electrically connected with the signal input terminal or a second power supply terminal, and a second electrode of the first transistor is electrically connected with the control node.

A control electrode of the second transistor is electrically connected with the pull-up node, a first electrode of the second transistor is electrically connected with the clock signal terminal, and a second electrode of the second transistor is electrically connected with the first output terminal.

A control electrode of the third transistor is electrically connected with the pull-up node, a first electrode of the third transistor is electrically connected with the clock signal terminal, and a second electrode of the third transistor is electrically connected with a second output terminal.

A first terminal of the capacitor is electrically connected with the pull-up node, and a second terminal of the capacitor is electrically connected with the first output terminal.

A control electrode of the fourth transistor is electrically connected with a total reset signal terminal, a first electrode of the fourth transistor is electrically connected with the pull-up node, and a second electrode of the fourth transistor is electrically connected with a first power supply terminal.

A control electrode of the fifth transistor is electrically connected with a first reset signal terminal, a first electrode of the fifth transistor is electrically connected with the pull-up node, and a second electrode of the fifth transistor is electrically connected with the first power supply terminal.

A control electrode of the sixth transistor is electrically connected with a second reset signal terminal, a first electrode of the sixth transistor is electrically connected with the first output terminal, and a second electrode of the sixth transistor is electrically connected with the first power supply terminal.

A control electrode of the seventh transistor is electrically connected with the signal input terminal, a first electrode of the seventh transistor is electrically connected with a first pull-down node, and a second electrode of the seventh transistor is electrically connected with the first power supply terminal.

A control electrode of the eighth transistor is electrically connected with the pull-up node, a first electrode of the eighth transistor is electrically connected with the first pull-down node, and a second electrode of the eighth transistor is electrically connected with the first power supply terminal.

A control electrode and a first electrode of the ninth transistor are respectively electrically connected with a fourth power supply terminal, and a second electrode of the ninth transistor is electrically connected with the first pull-down node.

A control electrode of the tenth transistor is electrically connected with the signal input terminal, a first electrode of the tenth transistor is electrically connected with a second pull-down node, and a second electrode of the tenth transistor is electrically connected with the first power supply terminal.

A control electrode of the eleventh transistor is electrically connected with the pull-up node, a first electrode of the eleventh transistor is electrically connected with the second pull-down node, and a second electrode of the eleventh transistor is electrically connected with the first power supply terminal.

A control electrode and a first electrode of the twelfth transistor are respectively electrically connected with a fifth power supply terminal, and a second electrode of the twelfth transistor is electrically connected with the second pull-down node.

A control electrode of the thirteenth transistor is electrically connected with the first pull-down node, a first electrode of the thirteenth transistor is electrically connected with the pull-up node, and a second electrode of the thirteenth transistor is electrically connected with the first power supply terminal.

A control electrode of the fourteenth transistor is electrically connected with the first pull-down node, a first electrode of the fourteenth transistor is electrically connected with the first output terminal, and a second electrode of the fourteenth transistor is electrically connected with a third power supply terminal.

A control electrode of the fifteenth transistor is electrically connected with the first pull-down node, a first electrode of the fifteenth transistor is electrically connected with the second output terminal, and a second electrode of the fifteenth transistor is electrically connected with the first power supply terminal.

A control electrode of the sixteenth transistor is electrically connected with the second pull-down node, a first electrode of the sixteenth transistor is electrically connected with the pull-up node, and a second electrode of the sixteenth transistor is electrically connected with the first power supply terminal.

A control electrode of the seventeenth transistor is electrically connected with the second pull-down node, a first electrode of the seventeenth transistor is electrically connected with the first output terminal, and a second electrode of the seventeenth transistor is electrically connected with the third power supply terminal.

A control electrode of the eighteenth transistor is electrically connected with the second pull-down node, a first electrode of the eighteenth transistor is electrically connected with the second output terminal, and a second electrode of the eighteenth transistor is electrically connected with the first power supply terminal.

A control electrode and a first electrode of the nineteenth transistor are respectively electrically connected with a first control signal terminal, and a second electrode of the nineteenth transistor is electrically connected with the signal input terminal.

A control electrode and a first electrode of the twentieth transistor are respectively electrically connected with the second control signal terminal, and a second electrode of the twentieth transistor is electrically connected with the signal input terminal.

A control electrode and a first electrode of the twenty-first transistor are respectively electrically connected with the control node, and a second electrode of the twenty-first transistor is electrically connected with the pull-up node.

In a second aspect, the present disclosure also provides a shift register including an input sub-circuit, an output sub-circuit, and a second control sub-circuit.

The input sub-circuit is electrically connected with a signal input terminal and a control node, respectively, and is configured to provide a signal to the control node under control of the signal input terminal.

The second control sub-circuit is electrically connected with the control node and a pull-up node, respectively, and is configured to provide a signal of the control node to the pull-up node under control of the signal of the control node.

The output sub-circuit is electrically connected with a first output terminal, the pull-up node, and a clock signal terminal, respectively, and is configured to provide a signal of the clock signal terminal to the first output terminal under control of a signal of the pull-up node.

In an exemplary implementation mode, the shift register further includes a first reset sub-circuit, a second reset sub-circuit, and a noise reduction sub-circuit; wherein the input sub-circuit includes a first transistor, the output sub-circuit includes a second transistor, a third transistor, and a capacitor, the second control sub-circuit includes a twenty-first transistor; the first reset sub-circuit includes a fourth transistor, the second reset sub-circuit includes a fifth transistor and a sixth transistor, and the noise reduction sub-circuit includes a seventh transistor to an eighteenth transistor.

A control electrode of the first transistor is electrically connected with the signal input terminal, a first electrode of the first transistor is electrically connected with the signal input terminal or a second power supply terminal, and a second electrode of the first transistor is electrically connected with the control node.

A control electrode of the second transistor is electrically connected with the pull-up node, a first electrode of the second transistor is electrically connected with the clock signal terminal, and a second electrode of the second transistor is electrically connected with the first output terminal.

A control electrode of the third transistor is electrically connected with the pull-up node, a first electrode of the third transistor is electrically connected with the clock signal terminal, and a second electrode of the third transistor is electrically connected with a second output terminal.

A first terminal of the capacitor is electrically connected with the pull-up node, and a second terminal of the capacitor is electrically connected with the first output terminal.

A control electrode of the fourth transistor is electrically connected with a total reset signal terminal, a first electrode of the fourth transistor is electrically connected with the pull-up node, and a second electrode of the fourth transistor is electrically connected with a first power supply terminal.

A control electrode of the fifth transistor is electrically connected with a first reset signal terminal, a first electrode of the fifth transistor is electrically connected with the pull-up node, and a second electrode of the fifth transistor is electrically connected with the first power supply terminal.

A control electrode of the sixth transistor is electrically connected with a second reset signal terminal, a first electrode of the sixth transistor is electrically connected with the first output terminal, and a second electrode of the sixth transistor is electrically connected with the first power supply terminal.

A control electrode of the seventh transistor is electrically connected with the signal input terminal, a first electrode of the seventh transistor is electrically connected with a first pull-down node, and a second electrode of the seventh transistor is electrically connected with the first power supply terminal.

A control electrode of the eighth transistor is electrically connected with the pull-up node, a first electrode of the eighth transistor is electrically connected with the first pull-down node, and a second electrode of the eighth transistor is electrically connected with the first power supply terminal.

A control electrode and a first electrode of the ninth transistor are respectively electrically connected with a fourth power supply terminal, and a second electrode of the ninth transistor is electrically connected with the first pull-down node.

A control electrode of the tenth transistor is electrically connected with the signal input terminal, a first electrode of the tenth transistor is electrically connected with a second pull-down node, and a second electrode of the tenth transistor is electrically connected with the first power supply terminal.

A control electrode of the eleventh transistor is electrically connected with the pull-up node, a first electrode of the eleventh transistor is electrically connected with the second pull-down node, and a second electrode of the eleventh transistor is electrically connected with the first power supply terminal.

A control electrode and a first electrode of the twelfth transistor are respectively electrically connected with a fifth power supply terminal, and a second electrode of the twelfth transistor is electrically connected with the second pull-down node.

A control electrode of the thirteenth transistor is electrically connected with the first pull-down node, a first electrode of the thirteenth transistor is electrically connected with the pull-up node, and a second electrode of the thirteenth transistor is electrically connected with the first power supply terminal.

A control electrode of the fourteenth transistor is electrically connected with the first pull-down node, a first electrode of the fourteenth transistor is electrically connected with the first output terminal, and a second electrode of the fourteenth transistor is electrically connected with a third power supply terminal.

A control electrode of the fifteenth transistor is electrically connected with the first pull-down node, a first electrode of the fifteenth transistor is electrically connected with the second output terminal, and a second electrode of the fifteenth transistor is electrically connected with the first power supply terminal.

A control electrode of the sixteenth transistor is electrically connected with the second pull-down node, a first electrode of the sixteenth transistor is electrically connected with the pull-up node, and a second electrode of the sixteenth transistor is electrically connected with the first power supply terminal.

A control electrode of the seventeenth transistor is electrically connected with the second pull-down node, a first electrode of the seventeenth transistor is electrically connected with the first output terminal, and a second electrode of the seventeenth transistor is electrically connected with the third power supply terminal.

A control electrode of the eighteenth transistor is electrically connected with the second pull-down node, a first electrode of the eighteenth transistor is electrically connected with the second output terminal, and a second electrode of the eighteenth transistor is electrically connected with the first power supply terminal.

A control electrode and a first electrode of the twenty-first transistor are respectively electrically connected with the control node, and a second electrode of the twenty-first transistor is electrically connected with the pull-up node.

In a third aspect, the present disclosure also provides a gate drive circuit, including a plurality of cascaded shift registers described above.

In an exemplary implementation mode, the gate drive circuit is disposed in a display apparatus, the display apparatus is further provided with a gate line, and a shift register includes an output sub-circuit.

In a state in which the output sub-circuit includes a first output terminal, a first output terminal of any stage of shift register is electrically connected with the gate line, a first output terminal of a current-stage shift register is electrically connected with a signal input terminal of a next-stage shift register, and the first output terminal of the current-stage shift register is electrically connected with a first reset signal terminal or a second reset signal terminal of a previous-stage shift register.

In an exemplary implementation mode, the gate drive circuit is disposed in a display apparatus, the display apparatus is further provided with a gate line, and a shift register includes an output sub-circuit.

In a state in which the output sub-circuit includes a first output terminal and a second output terminal, a first output terminal of any stage of shift register is electrically connected with the gate line, a second output terminal of a current-stage shift register is electrically connected with a signal input terminal of a next-stage shift register, and the second output terminal of the current-stage shift register is electrically connected with a first reset signal terminal or a second reset signal terminal of a previous-stage shift register.

In a fourth aspect, the present disclosure also provides a display apparatus, including the gate drive circuit described above.

In a fifth aspect, the present disclosure also provides a drive method of a shift register, configured to drive the shift register described above, the method includes: providing, by an input sub-circuit, a signal to a pull-up node under control of a signal of a signal input terminal; providing, by an output sub-circuit, a signal of a clock signal terminal to a first output terminal under control of a signal of the pull-up node; and providing, by a control sub-circuit, a signal of a control signal terminal to the signal input terminal under control of a signal of the control signal terminal.

In a sixth aspect, the present disclosure also provides a drive method of a shift register, configured to drive the shift register described above, the method includes: providing, by an input sub-circuit, a signal to a control node under control of a signal input terminal; providing, by a second control sub-circuit, a signal of the control node to a pull-up node under control of a signal of the control node; and providing, by an output sub-circuit, a signal of a clock signal terminal to a first output terminal under control of a signal of the pull-up node.

Other aspects may be comprehended after drawings and detailed descriptions are read and understood.

### BRIEF DESCRIPTION OF DRAWINGS

Accompanying drawings are intended to provide an understanding of technical solutions of the present application and constitute a part of the specification, and are used to explain the technical solutions of the present application together with embodiments of the present application, and do not constitute limitations on the technical solutions of the present application.

FIG. 1 is a schematic diagram of a structure of a shift register according to an embodiment of the present disclosure.

FIG. 2 is a first schematic diagram of a structure of a shift register according to an exemplary implementation mode.

FIG. 3 is a first schematic diagram of a connection of a first control sub-circuit according to an exemplary implementation mode.

FIG. 4 is a second schematic diagram of a connection of a first control sub-circuit according to an exemplary implementation mode.

FIG. 5 is a third schematic diagram of a connection of a first control sub-circuit according to an exemplary implementation mode.

FIG. 6 is a first equivalent circuit diagram of a first control sub-circuit according to an exemplary implementation mode.

FIG. 7 is second equivalent circuit diagram of a first control sub-circuit according to an exemplary implementation mode.

FIG. 8 is a third equivalent circuit diagram of a first control sub-circuit according to an exemplary implementation mode.

FIG. 9 is a first equivalent circuit diagram of an input sub-circuit according to an exemplary implementation mode.

FIG. 10 is a second equivalent circuit diagram of an input sub-circuit according to an exemplary implementation mode.

FIG. 11 is a first equivalent circuit diagram of an output sub-circuit according to an exemplary implementation mode.

FIG. 12 is a second equivalent circuit diagram of an output sub-circuit according to an exemplary implementation mode.

FIG. 13 is an equivalent circuit diagram of a first reset sub-circuit according to an exemplary implementation mode.

FIG. 14 is a second schematic diagram of a structure of a shift register according to an exemplary implementation mode.

FIG. 15 is an equivalent circuit diagram of a second reset sub-circuit according to an exemplary implementation mode.

FIG. 16 is an equivalent circuit diagram of a noise reduction sub-circuit according to an exemplary implementation mode.

FIG. 17 is a first equivalent circuit diagram of a shift register according to an exemplary implementation mode.

FIG. 18 is a second equivalent circuit diagram of a shift register according to an exemplary implementation mode.

FIG. 19 is a third equivalent circuit diagram of a shift register according to an exemplary implementation mode.

FIG. 20 is a fourth equivalent circuit diagram of a shift register according to an exemplary implementation mode.

FIG. 21 is a fifth equivalent circuit diagram of a shift register according to an exemplary implementation mode.

FIG. 22 is a sixth equivalent circuit diagram of a shift register according to an exemplary implementation mode.

FIG. 23 is a working timing diagram of the shift register provided in FIG. 17 and FIG. 20.

FIG. 24 is a working timing diagram of the shift register provided in FIG. 18 and FIG. 21.

FIG. 25 is a working timing diagram of the shift register provided in FIG. 19 and FIG. 22.

FIG. 26 is a schematic diagram of a structure of another shift register according to an embodiment of the present disclosure.

FIG. 27 is an equivalent circuit diagram of a shift register according to another exemplary embodiment.

FIG. 28 is a working timing diagram of the shift register provided in FIG. 27.

FIG. 29 is a first schematic diagram of cascade of a gate drive circuit.

FIG. 30 is a second schematic diagram of cascade of a gate drive circuit.

### DETAILED DESCRIPTION

To make objectives, technical solutions, and advantages of the present disclosure clearer, the embodiments of the present disclosure will be described in detail below with reference to the accompanying drawings. It is to be noted that implementation modes may be implemented in multiple different forms. Those of ordinary skills in the art may easily understand such a fact that modes and contents may be transformed into various forms without departing from the purpose and scope of the present disclosure. Therefore, the present disclosure should not be explained as being limited to contents recorded in following implementation modes only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to structures involved in the embodiments of the present disclosure, and other structures may be referred to conventional designs.

In the accompanying drawings, a size of each constituent element, a thickness of a layer, or a region may be exaggerated sometimes for clarity. Therefore, one mode of the present disclosure is not necessarily limited to the size, and a shape and a size of each component in the drawings do not reflect an actual scale. In addition, the accompanying drawings schematically illustrate ideal examples, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the accompanying drawings, not to indicate or imply that a referred apparatus or element must have a specific orientation or be structured and operated in the specific orientation but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a case that constituent elements are connected together through an element with a certain electrical action. The “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, other elements with various functions, etc.

In the present disclosure, “about” means that a boundary is not defined so strictly and numerical values within process and measurement error ranges are allowed.

The GOA technology is widely used in flat panel displays because it may reduce a bezel and simplify a bonding process. With an increasing demand for reliability of displays in the market. A GOA circuit includes a plurality of shift registers. In a working process of a shift register, some transistors in the shift register will be in a negative bias state, that is, a voltage value of a signal of a gate electrode of a transistor is smaller than a voltage value of a signal of a first electrode or a second electrode of the transistor. In a high temperature and high humidity environment, characteristics of a transistor in the negative bias state in the shift register will deteriorate, resulting in decrease of a turn-on voltage of the transistor in the negative bias state, which will increase a leakage current in the shift register and make the shift register unable to output normally, thus reducing a display effect of a display product.

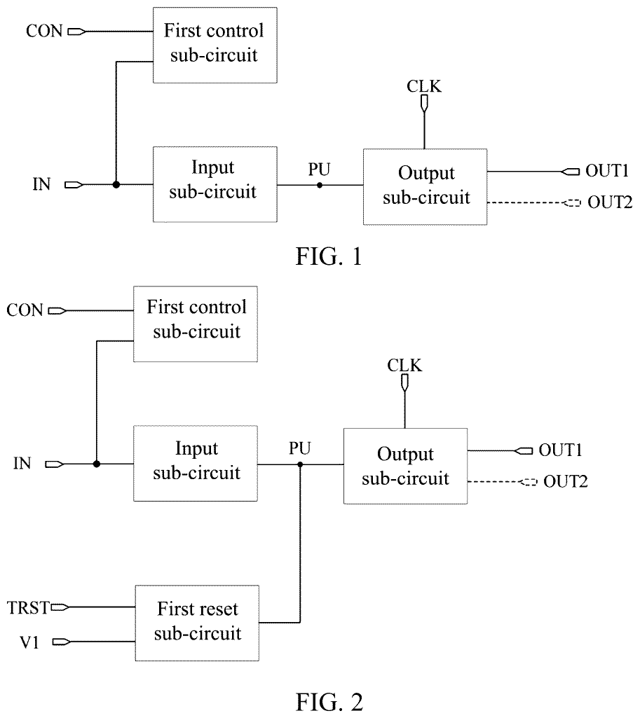

FIG. 1 is a schematic diagram of a structure of a shift register according to an embodiment of the present disclosure. As shown in FIG. 1, the shift register according to the embodiment of the present disclosure may include an input sub-circuit, an output sub-circuit, and a first control sub-circuit.

As shown in FIG. 1, the input sub-circuit is electrically connected with a signal input terminal IN and a pull-up node PU, respectively, and is configured to provide a signal to the pull-up node PU under control of a signal of the signal input terminal IN. The output sub-circuit is electrically connected with a first output terminal OUT1, the pull-up node PU, and a clock signal terminal CLK, respectively, and is configured to provide a signal of the clock signal terminal CLK to the first output terminal OUT1 under control of a signal of the pull-up node PU. The first control sub-circuit is electrically connected with a control signal terminal CON and the signal input terminal IN, respectively, and is configured to provide a signal of the control signal terminal CON to the signal input terminal IN under control of the signal of the control signal terminal CON.

In an exemplary implementation mode, a working process of the shift register includes a display phase and a non-display phase, wherein the display phase includes an output phase and a non-output phase, the non-output phase may include an input phase, and the input phase occurs before the output phase.

In an exemplary implementation mode, the non-display phase may include a power-on phase, a power-off phase, and a blank phase located between display phases.

In the input phase, a signal of the signal input terminal IN is an active level signal. Among them, an active level signal of a signal terminal refers to a signal that enables a transistor connected with the signal terminal to be turned on.

In an exemplary implementation mode, a signal of the first output terminal OUT1 is a single pulse signal. The first output terminal OUT1 may output a drive signal of a current stage, or may output the drive signal of the current stage and a cascade signal.

In an exemplary implementation mode, the signal of the clock signal terminal CLK is a clock signal in the display phase, and a pulse width is adjustable, and the signal of the clock signal terminal CLK is a direct current signal in the non-display phase.

In an exemplary implementation mode, the signal of the control signal terminal CON may be a single pulse signal in the display phase or the non-display phase.

In an exemplary implementation mode, the first control sub-circuit may control the signal of the signal input terminal IN, so that a voltage value of the signal of the signal input terminal IN is greater than a voltage value of the signal of the pull-up node PU in part of time periods of the non-output phase or the non-display phase, or the voltage value of the signal of the signal input terminal IN and the voltage value of the signal of the pull-up node PU in the output phase are less, thereby improving characteristics of some transistors in the output sub-circuit, reducing a leakage current of a shift register, ensuring normal output of the shift register, improving reliability of the shift register, and improving a display effect of a display product.

In an exemplary implementation mode, FIG. 2 is a first schematic diagram of a structure of a shift register according to an exemplary implementation mode. As shown in FIG. 2, the shift register may further include a reset sub-circuit. Among them, the first reset sub-circuit is electrically connected with a total reset signal terminal TRST, the pull-up node PU, and a first power supply terminal V1, respectively, and is configured to provide a signal of the first power supply terminal V1 to the pull-up node PU under control of the total reset signal terminal TRST.

In an exemplary implementation mode, the total reset signal terminal TRST has an active level signal in part of time periods of a non-display phase and an inactive level signal in a display phase. Among them, an inactive level signal of a signal terminal is a signal that enables a transistor connected with the signal terminal to be turned off.

In an exemplary implementation mode, the first power supply terminal V1 continuously supplies a low-level signal in the display phase and the non-display phase.

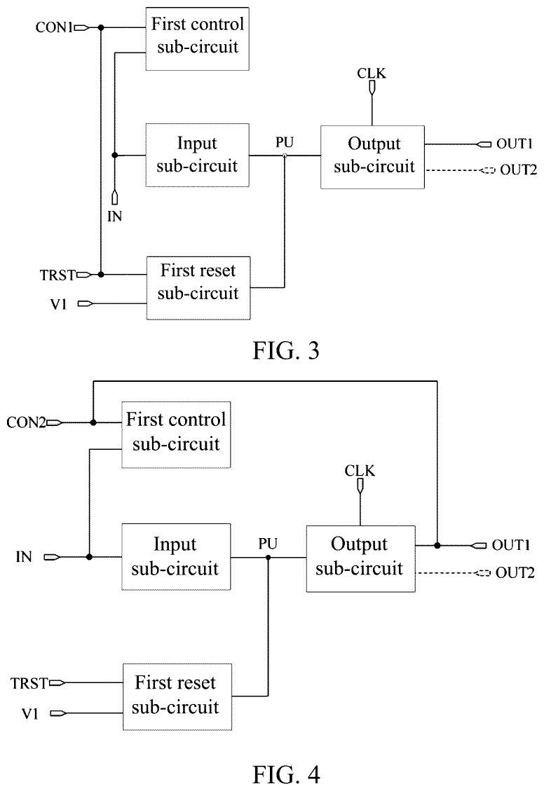

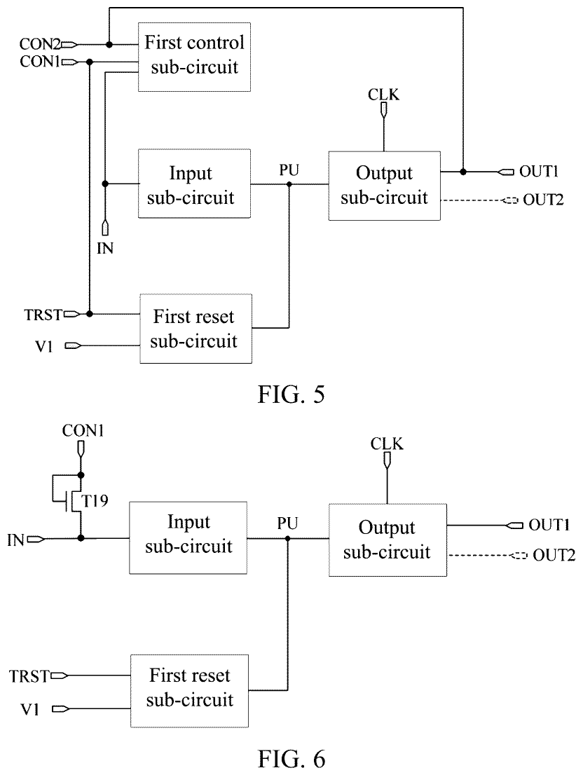

In an exemplary implementation mode, FIG. 3 is a first schematic diagram of a connection of a first control sub-circuit according to an exemplary implementation mode. FIG. 4 is a second schematic diagram of a connection of a first control sub-circuit according to an exemplary implementation mode. FIG. 5 is a third schematic diagram of a connection of a first control sub-circuit according to an exemplary implementation mode. As shown in FIG. 3 to FIG. 5, the control signal terminal CON includes at least one of a first control signal terminal CON1 and a second control signal terminal CON2. FIG. 3 is illustrated by taking a case that the control signal terminal CON includes the first control signal terminal CON1 as an example. FIG. 4 is illustrated by taking a case that the control signal terminal CON includes the second control signal terminal CON2 as an example. FIG. 5 is illustrated by taking a case that the control signal terminal CON includes the first control signal terminal CON1 and the second control signal terminal CON2 as an example.

In an exemplary implementation mode, as shown in FIG. 3 and FIG. 5, the first control signal terminal CON1 is electrically connected with the total reset signal terminal TRST, that is, the first control signal terminal CON1 may be a same signal terminal as the total reset signal terminal TRST, and for example, the first control signal terminal CON1 and the total reset signal terminal TRST may be connected with a same signal line, or may be connected with different signal lines having a same signal.

In an exemplary implementation mode, a signal of the first control signal terminal CON1 is an active level signal in part of time periods of the non-display phase.

In an exemplary implementation mode, as shown in FIGS. 4 and 5, the second control signal terminal CON2 is electrically connected with the first output terminal OUT1, that is, the second control signal terminal CON2 and the first output terminal OUT1 are a same signal terminal, and for example, the second control signal terminal CON2 and the first output terminal OUT1 may be connected with a same signal line, or may be connected with different signal lines having a same signal.

In an exemplary implementation mode, a signal of the second control signal terminal CON2 is an active level signal in the output phase.

In an exemplary implementation mode, FIG. 6 is a first equivalent circuit diagram of a first control sub-circuit according to an exemplary implementation mode. As shown in FIG. 6, in a state in which the control signal terminal CON includes the first control signal terminal CON1, the first control sub-circuit may include a nineteenth transistor T19. Among them, a control electrode and a first electrode of the nineteenth transistor T19 are respectively electrically connected with the first control signal terminal CON1, and a second electrode of the nineteenth transistor T19 is electrically connected with the signal input terminal IN.

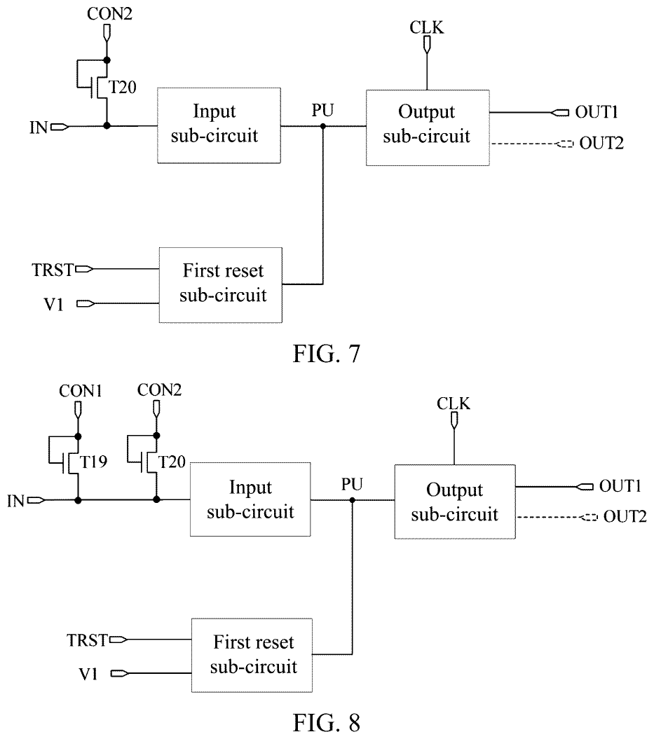

In an exemplary implementation mode, FIG. 7 is a second equivalent circuit diagram of a first control sub-circuit according to an exemplary implementation mode. As shown in FIG. 7, in a state in which the control signal terminal CON may include the second control signal terminal CON2, the first control sub-circuit includes a twentieth transistor T20. Among them, a control electrode and a first electrode of the twentieth transistor T20 are respectively electrically connected with the second control signal terminal CON2, and a second electrode of the twentieth transistor T20 is electrically connected with the signal input terminal IN.

In an exemplary implementation mode, FIG. 8 is a third equivalent circuit diagram of a first control sub-circuit according to an exemplary implementation mode. As shown in FIG. 8, in a state in which the control signal terminal CON includes the first control signal terminal CON1 and the second control signal terminal CON2, the control sub-circuit may include a nineteenth transistor T19 and a twentieth transistor T20. Among them, a control electrode and a first electrode of the nineteenth transistor T19 are respectively electrically connected with the first control signal terminal CON1, and a second electrode of the nineteenth transistor T19 is electrically connected with the signal input terminal IN; a control electrode and a first electrode of the twentieth transistor T20 are electrically connected with the second control signal terminal CON2, respectively, and a second electrode of the twentieth transistor T20 is electrically connected with the signal input terminal IN.

An exemplary structure of the first control sub-circuit is shown in FIG. 6 to FIG. 8. An implementation mode of a detection node control sub-circuit is not limited thereto, as long as its functions can be achieved.

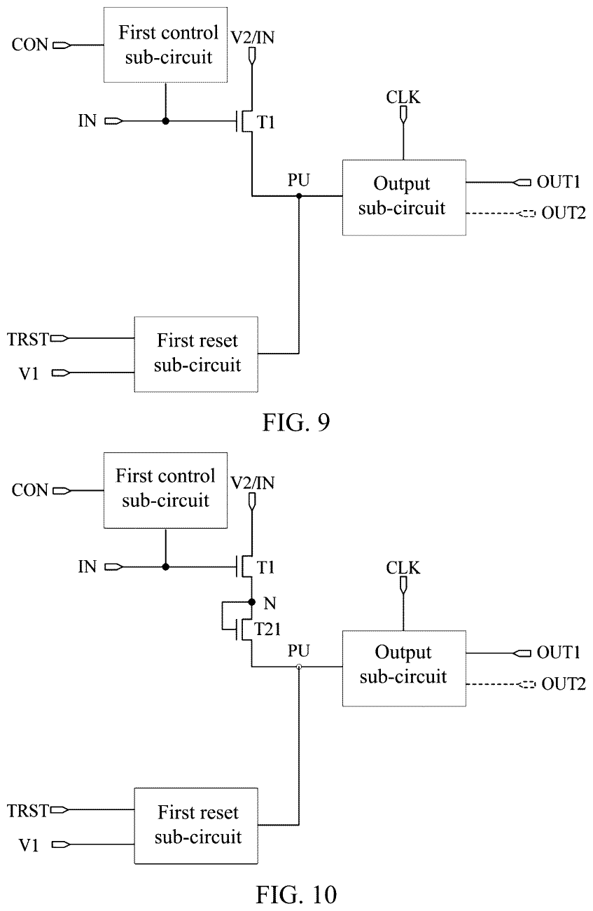

In an exemplary implementation mode, FIG. 9 is a first equivalent circuit diagram of an input sub-circuit according to an exemplary implementation mode. As shown in FIG. 9, the input sub-circuit may include a first transistor T1. A control electrode of the first transistor T1 is electrically connected with the signal input terminal IN, a first electrode of the first transistor T1 is electrically connected with the signal input terminal IN or a second power supply terminal V2, and a second electrode of the first transistor T1 is electrically connected with the pull-up node PU.

In an exemplary implementation mode, FIG. 10 is a second equivalent circuit diagram of an input sub-circuit according to an exemplary implementation mode. As shown in FIG. 10, the input sub-circuit may include a first transistor T1 and a twenty-first transistor T21. Among them, a control electrode of the first transistor T1 is electrically connected with the signal input terminal IN, a first electrode of the first transistor T1 is electrically connected with the signal input terminal IN or a second power supply terminal V2, and a second electrode of the first transistor T1 is electrically connected with a control node N; a control electrode and a first electrode of the twenty-first transistor T21 are respectively electrically connected with the control node N, and a second electrode of the twenty-first transistor T21 is electrically connected with the pull-up node PU.

In an exemplary implementation mode, the second power supply terminal V2 continuously supplies a high-level signal.

In an exemplary implementation mode, the twenty-first transistor is equivalent to a diode with unidirectional conduction.

In the exemplary implementation mode, since a voltage value of a signal of the pull-up node PU is greater than a voltage value of the signal input terminal IN in the output phase, the first transistor T1 is in a negative bias state in the output phase, and since a voltage value of a signal of the signal input terminal IN is greater than a voltage value of a signal of the pull-up node PU in part of time periods of the non-output phase and the non-display phase, the first transistor T1 is in a forward bias state in part of time periods of the non-output phase and the non-display phase, improving characteristics of the first transistor.

FIGS. 9 and 10 show exemplary structures of the input sub-circuit. An implementation mode of the input sub-circuit is not limited thereto, as long as its functions may be achieved.

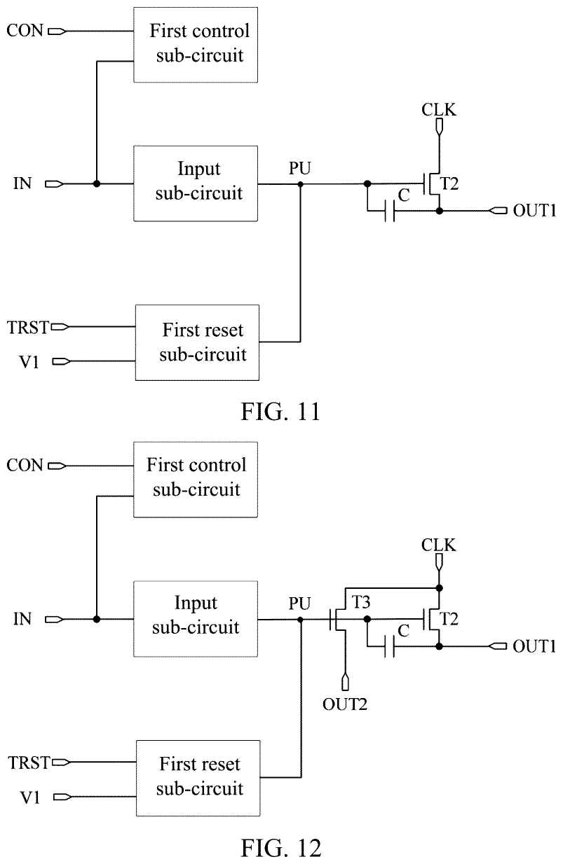

In an exemplary implementation mode, FIG. 11 is a first equivalent circuit diagram of an output sub-circuit according to an exemplary implementation mode. As shown in FIG. 11, when the output sub-circuit is electrically connected with the first output terminal OUT1, the output sub-circuit may include a second transistor T2 and a capacitor C. among them, a control electrode of the second transistor T2 is electrically connected with the pull-up node PU, a first electrode of the second transistor T2 is electrically connected with the clock signal terminal CLK, and a second electrode of the second transistor T2 is electrically connected with the first output terminal OUT1; a first terminal of the capacitor C is electrically connected with the pull-up node PU, and a second terminal of the capacitor C is electrically connected with the first output terminal OUT1.

As shown in FIG. 1 to FIG. 10, the output sub-circuit may be further electrically connected with a second output terminal OUT2 and is configured to provide a signal of the clock signal terminal CLK to the second output terminal OUT2 under control of the signal of the pull-up node PU. When the output sub-circuit is electrically connected with the first output terminal OUT1 and the second output terminal OUT2, the first output terminal OUT1 outputs a drive signal, and the second output terminal OUT2 outputs a cascade signal.

In an exemplary implementation mode, signals of the second output terminal OUT2 and the first output terminal OUT1 are the same.

In an exemplary implementation mode, FIG. 12 is a second equivalent circuit diagram of an output sub-circuit according to an exemplary implementation mode. As shown in FIG. 12, when the output sub-circuit is electrically connected with the first output terminal OUT1 and the second output terminal OUT2, the output sub-circuit may include a second transistor T2, a third transistor T3, and a capacitor C. Among them, a control electrode of the second transistor T2 is electrically connected with the pull-up node PU, a first electrode of the second transistor T2 is electrically connected with the clock signal terminal CLK, and a second electrode of the second transistor T2 is electrically connected with the first output terminal OUT1; a control electrode of the third transistor T3 is electrically connected with the pull-up node PU, a first electrode of the third transistor T3 is electrically connected with the clock signal terminal CLK, and a second electrode of the third transistor T3 is electrically connected with the second output terminal OUT2; a first terminal of the capacitor C is electrically connected with the pull-up node PU, and a second terminal of the capacitor C is electrically connected with the first output terminal OUT1.

In an exemplary implementation mode, the capacitor C may ensure stability of a signal of the pull-up node PU, and may also ensure stability of a signal of the first output terminal OUT1, and may improve reliability of the shift register.

FIGS. 11 and 12 show exemplary structures of the output sub-circuit. An implementation mode of the output sub-circuit is not limited thereto, as long as its functions may be achieved.

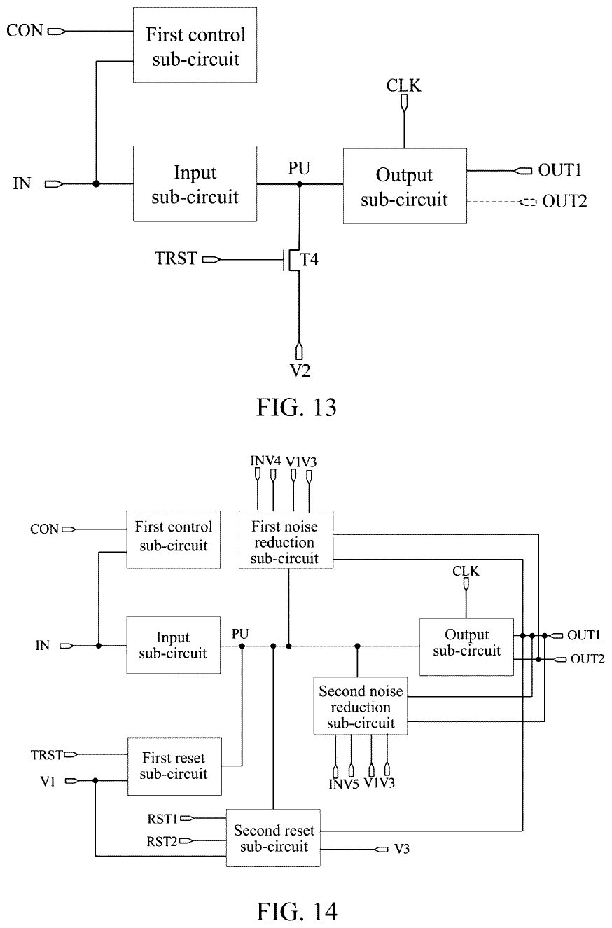

In an exemplary implementation mode, FIG. 13 is an equivalent circuit diagram of a first reset sub-circuit according to an exemplary implementation mode. As shown in FIG. 13, the first reset sub-circuit may include a fourth transistor T4. Among them, a control electrode of the fourth transistor T4 is electrically connected with the total reset signal terminal TRST, a first electrode of the fourth transistor T4 is electrically connected with the pull-up node PU, and a second electrode of the fourth transistor T4 is electrically connected with the first power supply terminal V1.

FIG. 13 shows an exemplary structure of the first reset sub-circuit. An implementation mode of the first reset sub-circuit is not limited thereto, as long as its functions may be achieved.

In an exemplary implementation mode, FIG. 14 is a second schematic diagram of a structure of a shift register according to an exemplary implementation mode. As shown in FIG. 14, the shift register may further include a second reset sub-circuit. Among them, the second reset sub-circuit is electrically connected with a first reset signal terminal RST1, a second reset signal terminal RST2, the pull-up node PU, the first output terminal OUT1, a first power supply terminal V1, and a third power supply terminal V3, respectively, and is configured to provide a signal of the first power supply terminal V1 to the pull-up node PU and provide a signal of the third power supply terminal V3 to the first output terminal OUT1 under control of signals of the first reset signal terminal RST1 and the second reset signal terminal RST2.

In an exemplary implementation mode, the first reset signal terminal RST1 and the second reset signal terminal RST2 have inactive level signals in the non-display phase and the output phase, and have active level signals in part of time periods of the non-output phase.

In an exemplary implementation mode, the non-output phase further includes a reset phase, and the reset phase occurs after the output phase. The first reset signal terminal RST1 and the second reset signal terminal RST2 have active level signals in the reset phase, and have inactive level signals in other phases except the reset phase.

In an exemplary implementation mode, the third power supply terminal V3 continuously supplies a low-level signal.

In an exemplary implementation mode, an absolute value of a voltage of the signal of the first power supply terminal V1 is greater than an absolute value of a voltage of the signal of the third power supply terminal V3.

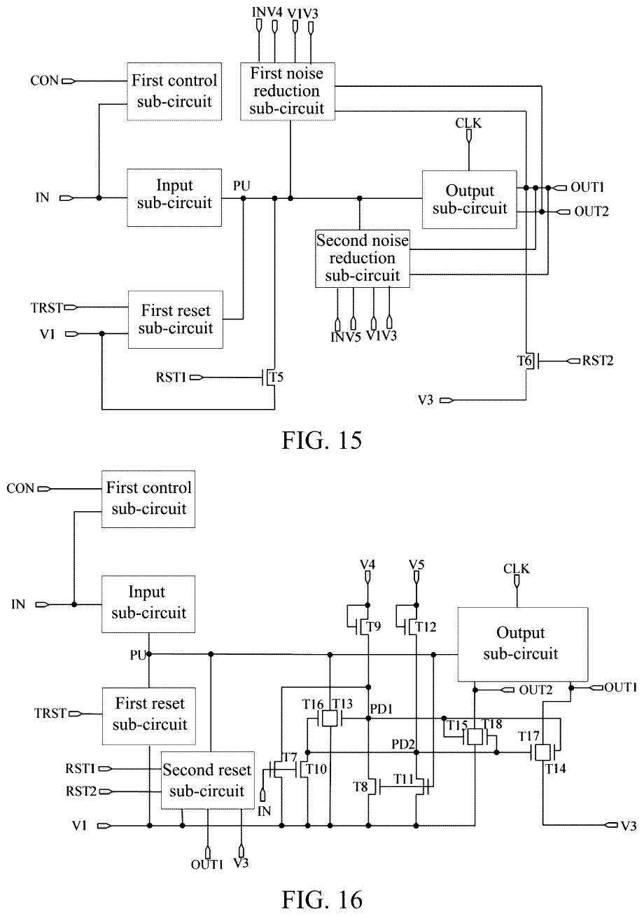

In an exemplary implementation mode, FIG. 15 is an equivalent circuit diagram of a second reset sub-circuit according to an exemplary implementation mode. As shown in FIG. 15, the second reset sub-circuit may include a fifth transistor T5 and a sixth transistor T6. Among them, a control electrode of the fifth transistor T5 is electrically connected with the first reset signal terminal RST1, a first electrode of the fifth transistor T5 is electrically connected with the pull-up node PU, and a second electrode of the fifth transistor T5 is electrically connected with the first power supply terminal V1; a control electrode of the sixth transistor T6 is electrically connected with the second reset signal terminal RST2, a first electrode of the sixth transistor T6 is electrically connected with the first output terminal OUT1, and a second electrode of the sixth transistor T6 is electrically connected with the third power supply terminal V3.

FIG. 15 shows an exemplary structure of the second reset sub-circuit. An implementation mode of the second reset sub-circuit is not limited thereto, as long as its functions may be achieved.

In an exemplary implementation mode, as shown in FIG. 14, the shift register may further include a noise reduction sub-circuit, and the noise reduction sub-circuit may include at least one of a first noise reduction sub-circuit and a second noise reduction sub-circuit. Among them, the first noise reduction sub-circuit is electrically connected with a fourth power supply terminal V4, the signal input terminal IN, the pull-up node PU, the first output terminal OUT1, the second output terminal OUT2, the first power supply terminal V1, and the third power supply terminal V3, respectively, and is configured to provide a signal of the first power supply terminal V1 to the pull-up node PU and the second output terminal OUT2, and provide a signal of the third power supply terminal V3 to a pull-down node under control of signals of the signal input terminal IN, the pull-up node PU, and the fourth power supply terminal V4; the second noise reduction sub-circuit is electrically connected with a fifth power supply terminal V5, the signal input terminal IN, the pull-up node PU, the first output terminal OUT1, the second output terminal OUT2, the first power supply terminal V1, and the third power supply terminal V3, respectively, and is configured to provide the signal of the first power supply terminal V1 to the pull-up node PU and the second output terminal OUT2, and provide the signal of the third power supply terminal V3 to the pull-down node under control of signals of the signal input terminal IN, the pull-up node PU, and the fifth power supply terminal V5. FIG. 14 is illustrated by taking a case that the noise reduction sub-circuit includes the first noise reduction sub-circuit and the second noise reduction sub-circuit as an example.

In an exemplary implementation mode, the signal of the third power supply terminal V3 is a low-level signal in the display phase and the non-display phase. An absolute value of a voltage of the signal of the first power supply terminal V1 is greater than an absolute value of a voltage of the signal of the third power supply terminal V3.

In an exemplary implementation mode, when the noise reduction sub-circuit includes the first noise reduction sub-circuit, the fourth power supply terminal V4 continuously supplies a high-level signal. When the noise reduction sub-circuit includes the second noise reduction sub-circuit, the fifth power supply terminal V5 continuously supplies a high-level signal.

In an exemplary implementation mode, when the noise reduction sub-circuit includes the first noise reduction sub-circuit and the second noise reduction sub-circuit, the fourth power supply terminal V4 and the fifth power supply terminal V5 have mutually inverted signals, and the fourth power supply terminal V4 and the fifth power supply terminal V5 do not have high-level signals simultaneously, for example, when the fourth power supply terminal V4 has a high-level signal, the fifth power supply terminal V5 has a low-level signal, or when the fourth power supply terminal V4 has a low-level signal, the fifth power supply terminal V5 has a high-level signal.

In an exemplary implementation mode, display frames may include first display frames and second display frames, and the first display frames and the second display frames may be alternately arranged. In a first display frame, a signal of the fourth power supply terminal V4 is a high-level signal, a signal of the fifth power supply terminal V5 is a low-level signal. In a second display frame, a signal of the fourth power supply terminal V4 is a low-level signal, and a signal of the fifth power supply terminal V5 is a high-level signal.

In an exemplary implementation mode, the first noise reduction sub-circuit and the second noise reduction sub-circuit do not reduce noise at the same time, lifetimes of transistors in the first noise reduction sub-circuit and the second noise reduction sub-circuit may be improved, and reliability of the shift register may be improved.

In an exemplary implementation mode, FIG. 16 is an equivalent circuit diagram of a noise reduction sub-circuit according to an exemplary implementation mode. FIG. 16 is illustrated by taking a case that the noise reduction sub-circuit includes the first noise reduction sub-circuit and the second noise reduction sub-circuit as an example. As shown in FIG. 16, the first noise reduction sub-circuit includes a seventh transistor T7, an eighth transistor T8, a ninth transistor T9, a thirteenth transistor T13, a fourteenth transistor T14, and a fifteenth transistor T15, and the second noise reduction sub-circuit includes a tenth transistor T10, an eleventh transistor T11, a twelfth transistor T12, a sixteenth transistor T16, a seventeenth transistor T17, and an eighteenth transistor T18. Among them, a control electrode of the seventh transistor T7 is electrically connected with the signal input terminal IN, a first electrode of the seventh transistor T7 is electrically connected with a first pull-down node PD1, and a second electrode of the seventh transistor T7 is electrically connected with the first power supply terminal V1; a control electrode of the eighth transistor T8 is electrically connected with the pull-up node PU, a first electrode of the eighth transistor T8 is electrically connected with the first pull-down node PD1, and a second electrode of the eighth transistor T8 is electrically connected with the first power supply terminal V1; a control electrode and a first electrode of the ninth transistor T9 are respectively electrically connected with the fourth power supply terminal V4, and a second electrode of the ninth transistor T9 is electrically connected with the first pull-down node PD1; a control electrode of the tenth transistor T10 is electrically connected with the signal input terminal IN, a first electrode of the tenth transistor T10 is electrically connected with a second pull-down node PD2, and a second electrode of the tenth transistor T10 is electrically connected with the first power supply terminal V1; a control electrode of the eleventh transistor T11 is electrically connected with the pull-up node PU, a first electrode of the eleventh transistor T11 is electrically connected with the second pull-down node PD2, and a second electrode of the eleventh transistor T11 is electrically connected with the first power supply terminal V1; a control electrode and a first electrode of the twelfth transistor T12 are electrically connected with the fifth power supply terminal V5, respectively, and a second electrode of the twelfth transistor T12 is electrically connected with the second pull-down node PD2; a control electrode of the thirteenth transistor T13 is electrically connected with the first pull-down node PD1, a first electrode of the thirteenth transistor T13 is electrically connected with the pull-up node PU, and a second electrode of the thirteenth transistor T13 is electrically connected with the first power supply terminal V1; a control electrode of the fourteenth transistor T14 is electrically connected with the first pull-down node PD1, a first electrode of the fourteenth transistor T14 is electrically connected with the first output terminal OUT1, and a second electrode of the fourteenth transistor T14 is electrically connected with the third power supply terminal V3; a control electrode of the fifteenth transistor T15 is electrically connected with the first pull-down node PD1, a first electrode of the fifteenth transistor T15 is electrically connected with the second output terminal OUT2, and a second electrode of the fifteenth transistor T15 is electrically connected with the first power supply terminal V1; a control electrode of the sixteenth transistor T16 is electrically connected with the second pull-down node PD2, a first electrode of the sixteenth transistor T16 is electrically connected with the pull-up node PU, and a second electrode of the sixteenth transistor T16 is electrically connected with the first power supply terminal V1; a control electrode of the seventeenth transistor T17 is electrically connected with the second pull-down node PD2, a first electrode of the seventeenth transistor T17 is electrically connected with the first output terminal OUT1, and a second electrode of the seventeenth transistor T17 is electrically connected with the third power supply terminal V3; a control electrode of the eighteenth transistor T18 is electrically connected with the second pull-down node PD2, a first electrode of the eighteenth transistor T18 is electrically connected with the second output terminal OUT2, and a second electrode of the eighteenth transistor T18 is electrically connected with the first power supply terminal V1.

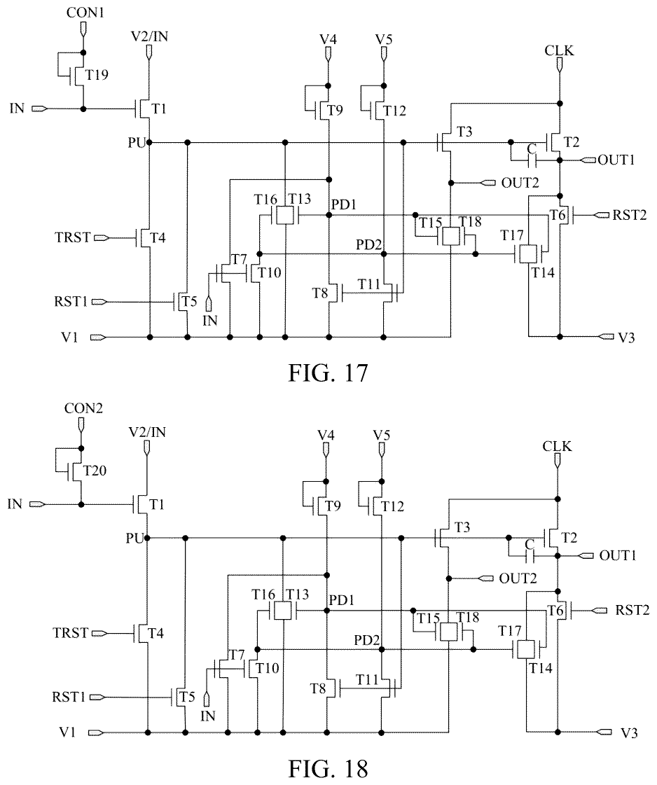

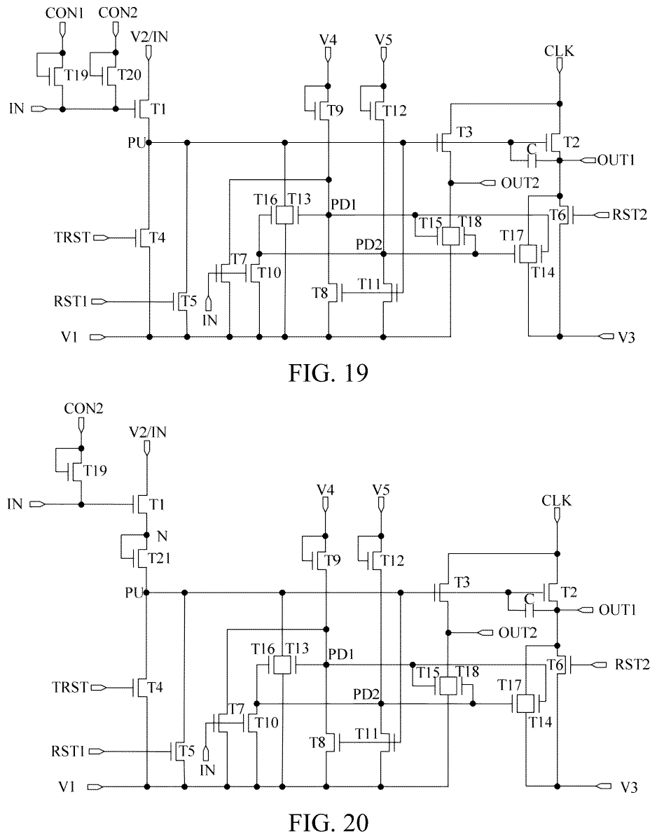

FIG. 17 is a first equivalent circuit diagram of a shift register according to an exemplary implementation mode, FIG. 18 is a second equivalent circuit diagram of a shift register according to an exemplary implementation mode, and FIG. 19 is a third equivalent circuit diagram of a shift register according to an exemplary implementation mode. As shown in FIGS. 17 to 19, in the shift register, an input sub-circuit includes a first transistor T1; an output sub-circuit includes a second transistor T2, a third transistor T3, and a capacitor C; a first control sub-circuit includes at least one of a nineteenth transistor T19 and a twentieth transistor T20; a first reset sub-circuit includes a fourth transistor T4; a second reset sub-circuit includes a fifth transistor T5 and a sixth transistor T6; a noise reduction sub-circuit includes a seventh transistor T7 to an eighteenth transistor T18. FIGS. 17 to 19 are illustrated by taking a case that the noise reduction sub-circuit includes a first noise reduction sub-circuit and a second noise reduction sub-circuit as an example. FIG. 17 is illustrated by taking a case that the first control sub-circuit includes the nineteenth transistor T19 as an example, FIG. 18 is illustrated by taking a case that the first control sub-circuit includes the twentieth transistor T20 as an example, and FIG. 19 is illustrated by taking a case that the first control sub-circuit includes the nineteenth transistor T19 and the twentieth transistor T20 as an example.

As shown in FIGS. 17 to 19, a control electrode of the first transistor T1 is electrically connected with the signal input terminal IN, a first electrode of the first transistor T1 is electrically connected with the signal input terminal IN or the second power supply terminal V2, and a second electrode of the first transistor T1 is electrically connected with the pull-up node PU; a control electrode of the second transistor T2 is electrically connected with the pull-up node PU, a first electrode of the second transistor T2 is electrically connected with the clock signal terminal CLK, and a second electrode of the second transistor T2 is electrically connected with the first output terminal OUT1; a control electrode of the third transistor T3 is electrically connected with the pull-up node PU, a first electrode of the third transistor T3 is electrically connected with the clock signal terminal CLK, and a second electrode of the third transistor T3 is electrically connected with the second output terminal OUT2; a first terminal of the capacitor C is electrically connected with the pull-up node PU, and a second terminal of the capacitor C is electrically connected with the first output terminal OUT1; a control electrode of the fourth transistor T4 is electrically connected with the total reset signal terminal TRST, a first electrode of the fourth transistor T4 is electrically connected with the pull-up node PU, and a second electrode of the fourth transistor T4 is electrically connected with the first power supply terminal V1; a control electrode of the fifth transistor T5 is electrically connected with the first reset signal terminal RST1, a first electrode of the fifth transistor T5 is electrically connected with the pull-up node PU, and a second electrode of the fifth transistor T5 is electrically connected with the first power supply terminal V1; a control electrode of the sixth transistor T6 is electrically connected with the second reset signal terminal RST2, a first electrode of the sixth transistor T6 is electrically connected with the first output terminal OUT1, and a second electrode of the sixth transistor T6 is electrically connected with the first power supply terminal V1; a control electrode of the seventh transistor T7 is electrically connected with the signal input terminal IN, a first electrode of the seventh transistor T7 is electrically connected with the first pull-down node PD1, and a second electrode of the seventh transistor T7 is electrically connected with the first power supply terminal V1; a control electrode of the eighth transistor T8 is electrically connected with the pull-up node PU, a first electrode of the eighth transistor T8 is electrically connected with the first pull-down node PD1, and a second electrode of the eighth transistor T8 is electrically connected with the first power supply terminal V1; a control electrode and a first electrode of the ninth transistor T9 are respectively electrically connected with the fourth power supply terminal V4, and a second electrode of the ninth transistor T9 is electrically connected with the first pull-down node PD1; a control electrode of the tenth transistor T10 is electrically connected with the signal input terminal IN, a first electrode of the tenth transistor T10 is electrically connected with the second pull-down node PD2, and a second electrode of the tenth transistor T10 is electrically connected with the first power supply terminal V1; a control electrode of the eleventh transistor T11 is electrically connected with the pull-up node PU, a first electrode of the eleventh transistor T11 is electrically connected with the second pull-down node PD2, and a second electrode of the eleventh transistor T11 is electrically connected with the first power supply terminal V1; a control electrode and a first electrode of the twelfth transistor T12 are electrically connected with the fifth power supply terminal V5, respectively, and a second electrode of the twelfth transistor T12 is electrically connected with the second pull-down node PD2; a control electrode of the thirteenth transistor T13 is electrically connected with the first pull-down node PD1, a first electrode of the thirteenth transistor T13 is electrically connected with the pull-up node PU, and a second electrode of the thirteenth transistor T13 is electrically connected with the first power supply terminal V1; a control electrode of the fourteenth transistor T14 is electrically connected with the first pull-down node PD1, a first electrode of the fourteenth transistor T14 is electrically connected with the first output terminal OUT1, and a second electrode of the fourteenth transistor T14 is electrically connected with the third power supply terminal V3; a control electrode of the fifteenth transistor T15 is electrically connected with the first pull-down node PD1, a first electrode of the fifteenth transistor T15 is electrically connected with the second output terminal OUT2, and a second electrode of the fifteenth transistor T15 is electrically connected with the first power supply terminal V1; a control electrode of the sixteenth transistor T16 is electrically connected with the second pull-down node PD2, a first electrode of the sixteenth transistor T16 is electrically connected with the pull-up node PU, and a second electrode of the sixteenth transistor T16 is electrically connected with the first power supply terminal V1; a control electrode of the seventeenth transistor T17 is electrically connected with the second pull-down node PD2, a first electrode of the seventeenth transistor T17 is electrically connected with the first output terminal OUT1, and a second electrode of the seventeenth transistor T17 is electrically connected with the third power supply terminal V3; a control electrode of the eighteenth transistor T18 is electrically connected with the second pull-down node PD2, a first electrode of the eighteenth transistor T18 is electrically connected with the second output terminal OUT2, and a second electrode of the eighteenth transistor T18 is electrically connected with the first power supply terminal V1; a control electrode and a first electrode of the nineteenth transistor T19 are respectively electrically connected with the first control signal terminal CON1, and a second electrode of the nineteenth transistor T19 is electrically connected with the signal input terminal IN; a control electrode and a first electrode of the twentieth transistor T20 are electrically connected with the second control signal terminal CON2, respectively, and a second electrode of the twentieth transistor T20 is electrically connected with the signal input terminal IN.

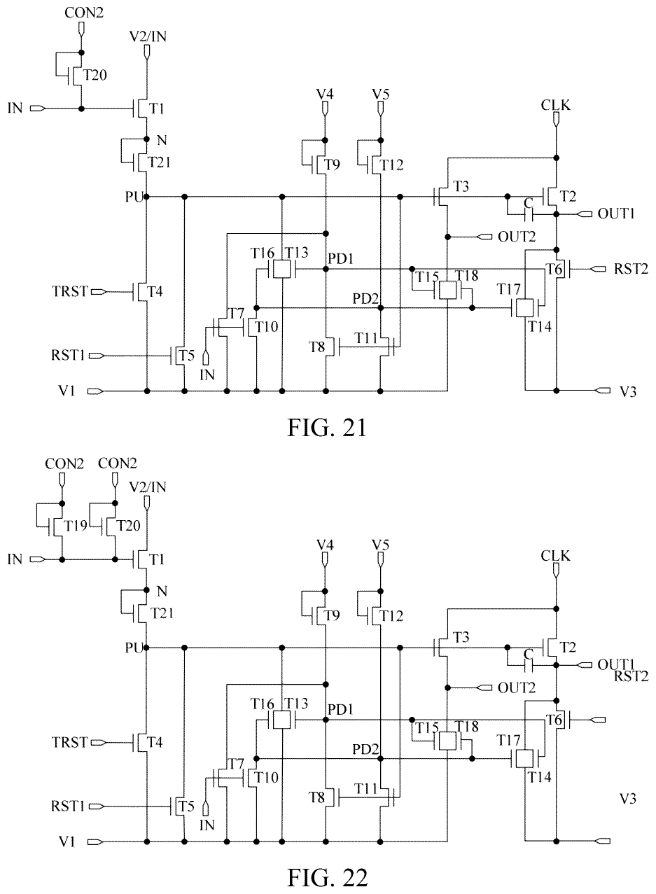

FIG. 20 is a fourth equivalent circuit diagram of a shift register according to an exemplary implementation mode, FIG. 21 is a fifth equivalent circuit diagram of a shift register according to an exemplary implementation mode, and FIG. 22 is a sixth equivalent circuit diagram of a shift register according to an exemplary implementation mode. As shown in FIGS. 20 to 22, the shift register further includes a first reset sub-circuit, a second reset sub-circuit, and a noise reduction sub-circuit. The input sub-circuit includes a first transistor T1 and a twenty-first transistor T21; the output sub-circuit includes a second transistor T2, a third transistor T3, and a capacitor C; the first control sub-circuit includes at least one of a nineteenth transistor T19 and a twentieth transistor T20; the first reset sub-circuit includes a fourth transistor T4, the second reset sub-circuit includes a fifth transistor T5 and a sixth transistor T6, and the noise reduction sub-circuit includes a seventh transistor T7 to an eighteenth transistor T18. FIGS. 20 to 22 are illustrated by taking a case that the noise reduction sub-circuit includes a first noise reduction sub-circuit and a second noise reduction sub-circuit as an example. FIG. 20 is illustrated by taking a case that the first control sub-circuit includes the nineteenth transistor T19 as an example, FIG. 21 is illustrated by taking a case that the first control sub-circuit includes the twentieth transistor T20 as an example, and FIG. 22 is illustrated by taking a case that the first control sub-circuit includes the nineteenth transistor T19 and the twentieth transistor T20 as an example.

As shown in FIGS. 20 to 22, a control electrode of the first transistor T1 is electrically connected with the signal input terminal IN, a first electrode of the first transistor T1 is electrically connected with the signal input terminal IN or the second power supply terminal V2, and a second electrode of the first transistor T1 is electrically connected with a control node; a control electrode of the second transistor T2 is electrically connected with the pull-up node PU, a first electrode of the second transistor T2 is electrically connected with the clock signal terminal CLK, and a second electrode of the second transistor T2 is electrically connected with the first output terminal OUT1; a control electrode of the third transistor T3 is electrically connected with the pull-up node PU, a first electrode of the third transistor T3 is electrically connected with the clock signal terminal CLK, and a second electrode of the third transistor T3 is electrically connected with the second output terminal OUT2; a first terminal of the capacitor C is electrically connected with the pull-up node PU, and a second terminal of the capacitor C is electrically connected with the first output terminal OUT1; a control electrode of the fourth transistor T4 is electrically connected with the total reset signal terminal TRST, a first electrode of the fourth transistor T4 is electrically connected with the pull-up node PU, and a second electrode of the fourth transistor T4 is electrically connected with the first power supply terminal V1; a control electrode of the fifth transistor T5 is electrically connected with the first reset signal terminal RST1, a first electrode of the fifth transistor T5 is electrically connected with the pull-up node PU, and a second electrode of the fifth transistor T5 is electrically connected with the first power supply terminal V1; a control electrode of the sixth transistor T6 is electrically connected with the second reset signal terminal RST2, a first electrode of the sixth transistor T6 is electrically connected with the first output terminal OUT1, and a second electrode of the sixth transistor T6 is electrically connected with the first power supply terminal V1; a control electrode of the seventh transistor T7 is electrically connected with the signal input terminal IN, a first electrode of the seventh transistor T7 is electrically connected with the first pull-down node PD1, and a second electrode of the seventh transistor T7 is electrically connected with the first power supply terminal V1; a control electrode of the eighth transistor T8 is electrically connected with the pull-up node PU, a first electrode of the eighth transistor T8 is electrically connected with the first pull-down node PD1, and a second electrode of the eighth transistor T8 is electrically connected with the first power supply terminal V1; a control electrode and a first electrode of the ninth transistor T9 are respectively electrically connected with the fourth power supply terminal V4, and a second electrode of the ninth transistor T9 is electrically connected with the first pull-down node PD1; a control electrode of the tenth transistor T10 is electrically connected with the signal input terminal IN, a first electrode of the tenth transistor T10 is electrically connected with the second pull-down node PD2, and a second electrode of the tenth transistor T10 is electrically connected with the first power supply terminal V1; a control electrode of the eleventh transistor T11 is electrically connected with the pull-up node PU, a first electrode of the eleventh transistor T11 is electrically connected with the second pull-down node PD2, and a second electrode of the eleventh transistor T11 is electrically connected with the first power supply terminal V1; a control electrode and a first electrode of the twelfth transistor T12 are electrically connected with the fifth power supply terminal V5, respectively, and a second electrode of the twelfth transistor T12 is electrically connected with the second pull-down node PD2; a control electrode of the thirteenth transistor T13 is electrically connected with the first pull-down node PD1, a first electrode of the thirteenth transistor T13 is electrically connected with the pull-up node PU, and a second electrode of the thirteenth transistor T13 is electrically connected with the first power supply terminal V1; a control electrode of the fourteenth transistor T14 is electrically connected with the first pull-down node PD1, a first electrode of the fourteenth transistor T14 is electrically connected with the first output terminal OUT1, and a second electrode of the fourteenth transistor T14 is electrically connected with the third power supply terminal V3; a control electrode of the fifteenth transistor T15 is electrically connected with the first pull-down node PD1, a first electrode of the fifteenth transistor T15 is electrically connected with the second output terminal OUT2, and a second electrode of the fifteenth transistor T15 is electrically connected with the first power supply terminal V1; a control electrode of the sixteenth transistor T16 is electrically connected with the second pull-down node PD2, a first electrode of the sixteenth transistor T16 is electrically connected with the pull-up node PU, and a second electrode of the sixteenth transistor T16 is electrically connected with the first power supply terminal V1; a control electrode of the seventeenth transistor T17 is electrically connected with the second pull-down node PD2, a first electrode of the seventeenth transistor T17 is electrically connected with the first output terminal OUT1, and a second electrode of the seventeenth transistor T17 is electrically connected with the third power supply terminal V3; a control electrode of the eighteenth transistor T18 is electrically connected with the second pull-down node PD2, a first electrode of the eighteenth transistor T18 is electrically connected with the second output terminal OUT2, and a second electrode of the eighteenth transistor T18 is electrically connected with the first power supply terminal V1; a control electrode and a first electrode of the nineteenth transistor T19 are respectively electrically connected with the first control signal terminal CON1, and a second electrode of the nineteenth transistor T19 is electrically connected with the signal input terminal IN; a control electrode and a first electrode of the twentieth transistor T20 are electrically connected with the second control signal terminal CON2, respectively, and a second electrode of the twentieth transistor T20 is electrically connected with the signal input terminal IN; a control electrode and a first electrode of the twenty-first transistor T21 are respectively electrically connected with the control node, and a second electrode of the twenty-first transistor T21 is electrically connected with the pull-up node PU.

In an exemplary implementation mode, transistors may be divided into N-type transistors and P-type transistors according to characteristics of the transistors. When a transistor is a P-type transistor, its turn-on voltage is a low-level voltage (e.g., 0 V, −5 V, −10 V, or another suitable voltage), and its turn-off voltage is a high-level voltage (e.g., 5 V, 10 V, or another suitable voltage). When a transistor is an N-type transistor, its turn-on voltage is a high-level voltage (e.g., 5 V, 10 V, or another suitable voltage), and its turn-off voltage is a low-level voltage (e.g., 0 V, −5 V, −10 V, or another suitable voltage).

In an exemplary implementation mode, all transistors in the shift register are N-type transistors. For example, all transistors in the shift register may be metal oxide transistors. Since a metal oxide transistor has a higher mobility and a low leakage current, all transistors in the shift register are metal oxide transistors, which may increase a refresh rate of a display product, realize high-frequency display, and also realize low-frequency display, thereby reducing power consumption.

For any of the shift registers provided in FIGS. 17 to 22, signals of the first power supply terminal V1 and the third power supply terminal V3 are low-level signals in the display phase and the non-display phase. A signal of the clock signal terminal CLK is a clock signal in the display phase, and a signal of the clock signal terminal CLK is a low-level signal in the non-display phase. The fourth power supply terminal V4 and the fifth power supply terminal V5 have constant voltage signals in any display frame. In a first display frame, the fourth power supply terminal V4 has a high-level signal, the ninth transistor T9 is continuously turned on, the fifth power supply terminal V5 has a low-level signal, and the twelfth transistor T12 is continuously turned off. In a second display frame, the fourth power supply terminal V4 has a low-level signal, the ninth transistor T9 is continuously turned off, the fifth power supply terminal V5 has a high-level signal, and the twelfth transistor T12 is continuously turned on. The fourth power supply terminal V4 switches from a first level signal to a second level signal during a time period when a signal of the total reset signal terminal TRST is an active level signal, and the fifth power supply terminal V5 switches from the second level signal to the first level signal during the time period when the signal of the total reset signal terminal TRST is the active level signal. For example, when the first level signal is a high-level signal, the second level signal is a low-level signal, and when the first level signal is a low-level signal, the second level signal is a high-level signal.

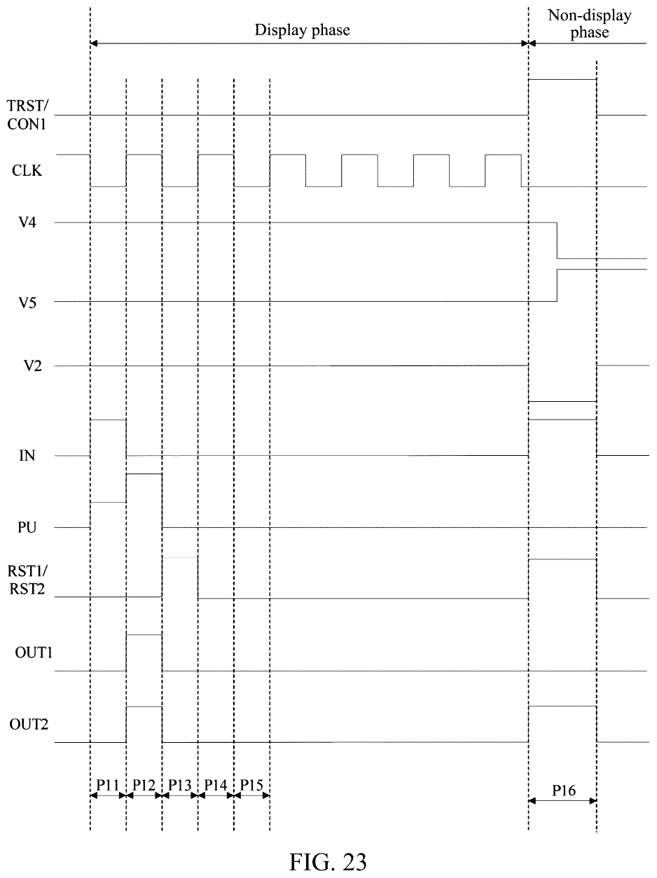

FIG. 23 is a working timing diagram of the shift register provided in FIG. 17 and FIG. 20. FIG. 23 is illustrated by taking a case in which all transistors in a shift register unit are N-type transistors as an example.

In the exemplary implementation mode, as shown in FIG. 23, when a signal of the total reset signal terminal TRST is an active level signal, a signal of the second power supply terminal V2 is a low-level signal, and when a signal of the total reset signal terminal TRST is an inactive level signal, a signal of the second power supply terminal V2 is a high-level signal. In conjunction with FIGS. 17 and 23, a working process of the shift register provided in FIG. 17 in the display phase may include following phases.

In a first phase P11, that is, an input phase, a signal of the signal input terminal IN is a high-level signal, and signals of the clock signal terminal CLK, the first reset signal terminal RST1, the second reset signal terminal RST2, the first control signal terminal CON1, and the total reset signal terminal TRST are low-level signals. The first control signal terminal CON1 has a low-level signal, the nineteenth transistor T19 is turned off, a signal of the signal input terminal IN is not pulled down, the signal of the signal input terminal IN is a high-level signal, the first transistor T1 is turned on, a high-level signal of the second power supply terminal V2 or a high-level signal of the signal input terminal IN is written into the pull-up node PU, the pull-up node PU is pulled up, the seventh transistor T7 and the tenth transistor T10 are turned on, and a low-level signal of the first power supply terminal V1 is written into the first pull-down node PD1 and the second pull-down node PD2. A signal of the pull-up node PU is a high-level signal, the second transistor T2 and the third transistor T3 are turned on, a low-level signal of the clock signal terminal CLK is written into the first output terminal OUT1 and the second output terminal OUT2, the eighth transistor T8 and the eleventh transistor T11 are turned on, and the low-level signal of the first power supply terminal V1 is continuously written into the first pull-down node PD1 and the second pull-down node PD2. The first pull-down node PD1 and the second pull-down node PD2 have continuously low-level signals, and the thirteenth transistor T13, the fourteenth transistor T14, the fifteenth transistor T15, the sixteenth transistor T16, the seventeenth transistor T17, and the eighteenth transistor T18 are turned off. In this phase, the signal of the pull-up node PU is a high-level signal, and signals of the first pull-down node PD1, the second pull-down node PD2, the first output terminal OUT1, and the second output terminal OUT2 are low-level signals.

In the first phase, when the shift register is in the first display frame, the ninth transistor T9 is turned on and the twelfth transistor T12 is turned off. Although the ninth transistor T9 is turned on, a high-level signal of the fourth power supply terminal V4 will pull up a signal of the first pull-down node PD1, but the signal of the first pull-down node PD1 will still be pulled down to a low-level signal since the seventh transistor T7, the eighth transistor T8, the tenth transistor T10, and the eleventh transistor T11 are continuously turned on. Similarly, when the shift register is in the second display frame, the ninth transistor T9 is turned off and the twelfth transistor T12 is turned on. Although the twelfth transistor T12 is turned on, a high-level signal of the fifth power supply terminal V5 will pull up a signal of the second pull-down node PD2, but the signal of the second pull-down node PD2 is still pulled down to a low-level signal since the seventh transistor T7, the eighth transistor T8, the tenth transistor T10, and the eleventh transistor T11 are continuously turned on. Regardless of whether the shift register is in the first display frame or the second display frame, the first pull-down node PD1 and the second pull-down node PD2 continue to have low-level signals in the first phase.

In a second phase P12, that is, an output phase, the clock signal terminal CLK has a high-level signal, and signals of the first control signal terminal CON1, the signal input terminal IN, the first reset signal terminal RST1, the second reset signal terminal RST2, and the total reset signal terminal TRST are low-level signals. A signal of the first control signal terminal CON1 is a low-level signal, the nineteenth transistor T19 is turned off, a signal of the signal input terminal IN is a low-level signal, the first transistor T1, the seventh transistor T7, and the tenth transistor T10 are turned off, under a bootstrap action of the capacitor C, the pull-up node PU is pulled up, the second transistor T2 and the third transistor T3 are turned on, the high-level signal of the clock signal terminal CLK is written into the first output terminal OUT1 and the second output terminal OUT2, the eighth transistor T8 and the eleventh transistor T11 are turned on, a low-level signal of the first power supply terminal V1 is continuously written into the first pull-down node PD1 and the second pull-down node PD2, and the first pull-down node PD1 and the second pull-down node PD2 continue to have low-level signals, and the thirteenth transistor T13, the fourteenth transistor T14, the fifteenth transistor T15, the sixteenth transistor T16, the seventeenth transistor T17, and the eighteenth transistor T18 are turned off. In this phase, signals of the pull-up node PU, the first output terminal OUT1, and the second output terminal OUT2 are high-level signals, and signals of the first pull-down node PD1 and the second pull-down node PD2 are low-level signals.

In the second phase, when the shift register is in the first display frame, the ninth transistor T9 is turned on and the twelfth transistor T12 is turned off. Although the ninth transistor T9 is turned on and the high-level signal of the fourth power supply terminal V4 will pull up a signal of the first pull-down node PD1, but the signal of the first pull-down node PD1 is still pulled down to a low-level signal since the eighth transistor T8 and the eleventh transistor T11 are continuously turned on. Similarly, when the shift register is in the second display frame, the ninth transistor T9 is turned off and the twelfth transistor T12 is turned on. Although the twelfth transistor T12 is turned on, the high-level signal of the fifth power supply terminal V5 will pull up a signal of the second pull-down node PD2, but the signal of the second pull-down node PD2 is still pulled down to a low-level signal since the eighth transistor T8 and the eleventh transistor T11 are continuously turned on. Regardless of whether the shift register is in the first display frame or the second display frame, the first pull-down node PD1 and the second pull-down node PD2 continue to have low-level signals in the second phase.

In the second phase, a voltage value of the signal of the signal input terminal IN is less than a voltage value of a signal of the pull-up node PU, so that the first transistor T1 is in a negative bias state, and a turn-on voltage of the first transistor T1 becomes smaller.

In a third phase P13, that is, a reset phase, the first reset signal terminal RST1 and the second reset signal terminal RST2 have high-level signals, and signals of the signal input terminal IN, the first control signal terminal CON1, the total reset signal terminal TRST, and the clock signal terminal CLK are low-level signals. Signals of the first reset signal terminal RST1 and the second reset signal terminal RST2 are high-level signals, the fifth transistor T5 and the sixth transistor T6 are turned on, the low-level signal of the first power supply terminal V1 is written into the pull-up node PU, the signal of the pull-up node PU is pulled down, the low-level signal of the third power supply terminal V3 is written into the first output terminal OUT1, a signal of the first output terminal OUT1 is pulled down, a signal of the first control signal terminal CON1 is a low-level signal, the nineteenth transistor T19 is turned off, a signal of the signal input terminal IN is a low-level signal, the first transistor T1, the seventh transistor T7, and the tenth transistor T10 are turned off, the pull-up node PU has a low-level signal, the eighth transistor T8 and the eleventh transistor T11 are turned off, and the first pull-down node PD1 and the second pull-down node PD2 are not pulled down by the low-level signal of the first power supply terminal V1. When the shift register is in the first display frame, the ninth transistor T9 is turned on, the high-level signal of the fourth power supply terminal V4 is written into the first pull-down node PD1, the thirteenth transistor T13, fourteenth transistor T14, and fifteenth transistor T15 are turned on, the low-level signal of the first power supply terminal V1 is written into the pull-up node PU and the second output terminal OUT2, the low-level signal of the third power supply terminal V3 is written into the first output terminal OUT1, the twelfth transistor T12 is turned off, the second pull-down node PD2 holds the low-level signal of a previous phase, and the sixteenth transistor T16, the seventeenth transistor T17, and the eighteenth transistor T18 are turned off. Or when the shift register is in the second display frame, the twelfth transistor T12 is turned on, the high-level signal of the fifth power supply terminal V5 is written into the second pull-down node PD2, the sixteenth transistor T16, the seventeenth transistor T17, and the eighteenth transistor T18 are turned on, the low-level signal of the first power supply terminal V1 is written into the pull-up node PU and the second output terminal OUT2, the low-level signal of the third power supply terminal V3 is written into the first output terminal OUT1, the ninth transistor T9 is turned off, the first pull-down node PD1 holds the low-level signal of the previous phase, and the thirteenth transistor T13, the fourteenth transistor T14, and the fifteenth transistor T15 are turned off.

In a fourth phase P14, that is, a first noise reduction phase, a signal of the clock signal terminal CLK is a high-level signal, and the signal input terminal IN, the first reset signal terminal RST1, the second reset signal terminal RST2, the first control signal terminal CON1, and the total reset signal terminal TRST have low-level signals. A signal of the signal input terminal IN is a low-level signal, the first transistor T1, the seventh transistor T7, and the tenth transistor T10 are turned off, a signal of the first control signal terminal CON1 is a low-level signal, the nineteenth transistor T19 is turned off, the signal of the second power supply terminal V2 or the signal input terminal IN cannot be written into the pull-up node PU, a signal of the pull-up node PU holds a low-level signal of a previous phase, the second transistor T2, the third transistor T3, the eighth transistor T8, and the eleventh transistor T11 are turned off, and the first pull-down node PD1 and the second pull-down node PD2 are not pulled down by the low-level signal of the first power supply terminal V1. When the shift register is in the first display frame, the ninth transistor T9 is turned on, the high-level signal of the fourth power supply terminal V4 is written into the first pull-down node PD1, the thirteenth transistor T13, the fourteenth transistor T14, and the fifteenth transistor T15 are turned on, the low-level signal of the first power supply terminal VI is written into the pull-up node PU and the second output terminal OUT2, the low-level signal of the third power supply terminal V3 is written into the first output terminal OUT1, the twelfth transistor T12 is turned off, the second pull-down node PD2 holds the low-level signal of the previous phase, and the sixteenth transistor T16, the seventeenth transistor T17, and the eighteenth transistor T18 are turned off. Or when the shift register is in the second display frame, the twelfth transistor T12 is turned on, the high-level signal of the fifth power supply terminal V5 is written into the second pull-down node PD2, the sixteenth transistor T16, the seventeenth transistor T17, and the eighteenth transistor T18 are turned on, the low-level signal of the first power supply terminal V1 is written into the pull-up node PU and the second output terminal OUT2, the low-level signal of the third power supply terminal V3 is written into the first output terminal OUT1, the ninth transistor T9 is turned off, the first pull-down node PD1 holds the low-level signal of the previous phase, and the thirteenth transistor T13, the fourteenth transistor T14, and the fifteenth transistor T15 are turned off.

In a fifth phase P15, that is, a second noise reduction phase, the clock signal terminal CLK, the signal input terminal IN, the first reset signal terminal RST1, the second reset signal terminal RST2, the first control signal terminal CON1, and the total reset signal terminal TRST have low-level signals. A signal of the signal input terminal IN is a low-level signal, the first transistor T1, the seventh transistor T7, and the tenth transistor T10 are turned off, a signal of the first control signal terminal CON1 is a low-level signal, the nineteenth transistor T19 is turned off, the signal of the second power supply terminal V2 or the signal input terminal IN cannot be written into the pull-up node PU, a signal of the pull-up node PU holds a low-level signal of a previous phase, the second transistor T2, the third transistor T3, the eighth transistor T8, and the eleventh transistor T11 are turned off, and the first pull-down node PD1 and the second pull-down node PD2 are not pulled down by the low-level signal of the first power supply terminal V1. When the shift register is in the first display frame, the ninth transistor T9 is turned on, the high-level signal of the fourth power supply terminal V4 is written into the first pull-down node PD1, the thirteenth transistor T13, the fourteenth transistor T14, and the fifteenth transistor T15 are turned on, the low-level signal of the first power supply terminal V1 is written into the pull-up node PU and the second output terminal OUT2, the low-level signal of the third power supply terminal V3 is written into the first output terminal OUT1, the twelfth transistor T12 is turned off, the second pull-down node PD2 holds the low-level signal of the previous phase, and the sixteenth transistor T16, the seventeenth transistor T17, and the eighteenth transistor T18 are turned off. Or when the shift register is in the second display frame, the twelfth transistor T12 is turned on, the high-level signal of the fifth power supply terminal V5 is written into the second pull-down node PD2, the sixteenth transistor T16, the seventeenth transistor T17, and the eighteenth transistor T18 are turned on, the low-level signal of the first power supply terminal V1 is written into the pull-up node PU and the second output terminal OUT2, the low-level signal of the third power supply terminal V3 is written into the first output terminal OUT1, the ninth transistor T9 is turned off, the first pull-down node PD1 holds the low-level signal of the previous phase, and the thirteenth transistor T13, the fourteenth transistor T14, and the fifteenth transistor T15 are turned off.

The working process of the shift register further includes a plurality of fourth phases P14 and a plurality of fifth phases P15, and a fourth phase P14 and a fifth phase P15 are alternately operated.

The fourth phase P14 and the fifth phase P15 may ensure that signals of the pull-up node PU, the first output terminal OUT1, and the second output terminal OUT2 of the shift register are continuously low-level signals, and may reduce a noise of the shift register and improve reliability of the shift register.

As shown in FIG. 23, a working process of the shift register provided in FIG. 17 in the non-display phase may include following phases.

In a sixth phase P16, signals of the total reset signal terminal TRST and the first control signal terminal CON1 are high-level signals, the fourth transistor T4 and the nineteenth transistor T19 are turned on, a high-level signal of the first control signal terminal CON1 is written into the signal input terminal IN, a signal of the signal input terminal IN is high-level signal, and a path is formed between the signal input terminal IN or the second power supply terminal V2 and the first power supply terminal V1, so that a voltage value of a signal of the pull-up node PU is less than a voltage value of the signal of the signal input terminal IN. In addition, since total reset signal terminals TRST with which all the shift registers are connected have high-level signals at the same time, signals of signal input terminals IN with which all the shift registers are connected are all high-level signals. Due to a cascade relationship of shift registers, a second output terminal OUT2 of a current-stage shift register will be electrically connected with signal input terminals IN of shift registers of other stages, and a first reset signal terminal RST1 and a second reset signal terminal RST2 of the current-stage shift register will be electrically connected with second output terminals OUT2 of the shift register of other stages. Therefore, signals of second output terminals OUT2, first reset signal terminals RST1, and second reset signal terminals RST2 of all shift registers are high-level signals in the sixth phase P16, signals of the first reset signal terminal RST1 and the second reset signal terminal RST2 are high-level signals, the signal of the first power supply terminal V1 is written into the pull-up node PU, and the signal of the third power supply terminal V3 is written into the first output terminal OUT1, which may prevent the shift register from being output in the non-display phase and ensure reliability of the shift register.

Since a voltage value of the signal of the signal input terminal IN in the sixth phase is greater than a voltage value of the signal of the pull-up node PU, the first transistor Tl is in a forward bias state, and a turn-on voltage of the first transistor T1 becomes larger, transistor characteristic drift caused by the first transistor T1 being in the negative bias state in the second phase may be improved, and transistor characteristics of the first transistor T1 may be restored.

In an exemplary implementation mode, since the second power supply terminal V2 has a low-level signal in the sixth phase P16 and the signal of the signal input terminal IN is a high-level signal, a voltage value of a signal of a pull-up node PU of a shift register provided with a first transistor T1 connected with the second power supply terminal V2 in the sixth phase P16 is less than a voltage value of a signal of a pull-up node PU of a shift register provided with a first transistor T1 connected with the signal input terminal in the sixth phase P16. That is, the shift register provided with the first transistor T1 connected with the second power supply terminal V2 improves transistor characteristic drift caused by the first transistor T1 being in the negative bias state in the second phase more strongly than the shift register provided with the first transistor T1 connected with the signal input terminal improves transistor characteristic drift caused by the first transistor T1 being in the negative bias state in the second phase.

Compared with the shift register provided in FIG. 17, the shift register provided in FIG. 20 has the twenty-first transistor T21. In conjunction with FIGS. 20 and 23, a working process of the shift register provided in FIG. 20 in the display phase may include following phases.

Compared with the shift register provided in FIG. 17 in the first phase P11, the shift register provided in FIG. 20 in the first phase P11 has same working processes of the first transistor T1 to the nineteenth transistor T19, except that the first transistor T1 is turned on, the high-level signal of the second power supply terminal V2 or the signal input terminal IN is written into the control node N, the twenty-first transistor T21 is turned on, a high-level signal of the control node N is written into the pull-up node PU, and the pull-up node PU is pulled up by the signal of the control node N.

Compared with the shift register provided in FIG. 17 in the second phase P12, the shift register provided in FIG. 20 in the second phase P12 has same working processes of the first transistor T1 to the nineteenth transistor T19, except that the signal of the control node N holds a high-level signal of a previous phase, and the twenty-first transistor T21 is continuously turned on.

In the second phase, a voltage value of the signal of the signal input terminal IN is smaller than a voltage value of the signal of the control node N, so that the first transistor Tl is in a negative bias state, and the turn-on voltage of the first transistor T1 becomes smaller. Compared with the shift register provided in FIG. 17, in the shift register provided in FIG. 20, due to presence of the twenty-first transistor T21, a voltage value of the signal of the control node N in the second phase is smaller than a voltage value of the signal of the pull-up node PU, that is, an absolute value of a difference value between a voltage value of the signal of the signal input terminal and a voltage value of the signal of the control node N in the shift register provided in FIG. 20 is smaller than an absolute value of a difference value between a voltage value of the signal of the signal input terminal and a voltage value of the signal of the pull-up node in the shift register provided in FIG. 17, that is, a degree of negative bias of the first transistor in the shift register provided in FIG. 20 is smaller than a degree of negative bias of the first transistor in the shift register provided in FIG. 17, and the shift register provided in FIG. 20 may prevent characteristic drift of the first transistor to some extent.

Compared with the shift register provided in FIG. 17 in the third phase P13, the shift register provided in FIG. 20 in the third phase P13 has same working processes of the first transistor T1 to the nineteenth transistor T19, except that the control node N holds a high-level signal of a previous phase, the twenty-first transistor T21 is turned on, and the twenty-first transistor T21 is turned off since the low-level signal of the pull-up node PU is also written into the control node N.

The control node N is pulled down to have a low-level signal in the third phase, the twenty-first transistor T21 is turned off. A working process of the shift register provided in FIG. 20 in the fourth phase P14 is the same as a working process of the shift register provided in FIG. 17 in the fourth phase P14, and a working process of the shift register provided in FIG. 20 in the fifth phase P15 is the same as a working process of the shift register provided in FIG. 17 in the fifth phase P15, which will not be repeated here.

A working process of the shift register provided in FIG. 20 in the non-display phase may include following phases.

In a sixth phase P16, when the first transistor T1 is electrically connected with the signal input terminal IN, working processes of the first transistor T1 to the nineteenth transistor T19 in the shift register provided in FIG. 20 is the same as working processes of the first transistor T1 to the nineteenth transistor T19 in the shift register provided in FIG. 17, except that the first transistor T1 is turned on, the high-level signal of the signal input terminal IN is written into the control node N, the twenty-first transistor T21 is turned on, and a path is formed between the signal input terminal IN and the first power supply terminal V1, so that a voltage value of the signal of the control node N is smaller than a voltage value of the signal of the signal input terminal IN. When the first transistor T1 is electrically connected with the second power supply terminal V2, working processes of the first transistor T1 to the nineteenth transistor T19 in the shift register provided in FIG. 20 is the same as working processes of the first transistor T1 to the nineteenth transistor T19 in the shift register provided in FIG. 17, except that the first transistor T1 is turned on, the low-level signal of the second power supply terminal V2 is written into the control node N, the twenty-first transistor T21 is turned off, and a voltage value of the signal of the control node N is smaller than a voltage value of the signal of the signal input terminal IN.

Since a voltage value of the signal of the signal input terminal IN in the sixth phase is greater than a voltage value of the signal of the pull-up node PU, the first transistor Tl is in a forward bias state, and a turn-on voltage of the first transistor T1 becomes larger, transistor characteristic drift caused by the first transistor T1 being in a negative bias state in the second phase may be improved, and transistor characteristics of the first transistor T1 may be restored.

When the shift register provided in FIG. 17 is compared with the shift register provided in FIG. 20, and their first transistors T1 are electrically connected with the signal input terminal IN, a resistance of the path between the signal input terminal IN and the first power supply terminal V1 of the shift register provided in FIG. 20 in the sixth phase is greater than a resistance of the path between the signal input terminal IN and the first power supply terminal V1 of the shift register provided in FIG. 17 in the sixth phase. Therefore, a voltage value of the signal of the control node N of the shift register provided in FIG. 20 is smaller than a voltage value of the signal of the pull-up node PU of the shift register provided in FIG. 17, that is, a degree of forward bias of the first transistor T1 in the shift register provided in FIG. 20 is greater than a degree of forward bias of the first transistor T1 in the shift register provided in FIG. 17.

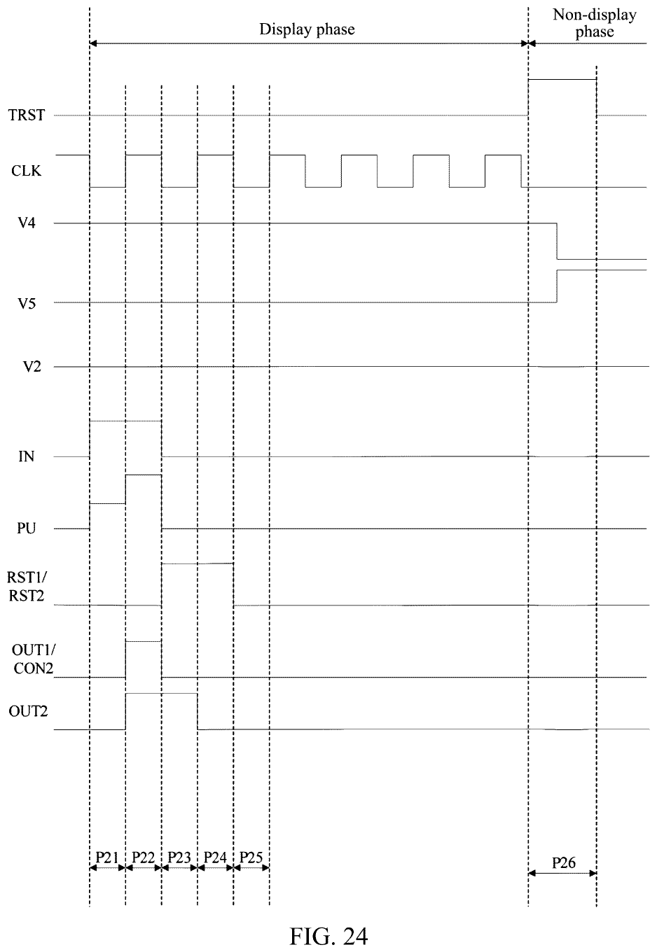

FIG. 24 is a working timing diagram of the shift register provided in FIG. 18 and FIG. 21. FIG. 24 is illustrated by taking a case in which all transistors in a shift register unit are N-type transistors as an example.

In an exemplary implementation mode, the second power supply terminal V2 has a direct current signal, which is a high-level signal.

In conjunction with FIGS. 18 and 24, a working process of the shift register provided in FIG. 18 in the display phase may include following phases.

In a first phase P21, that is, an input phase, a signal of the signal input terminal IN is a high-level signal, and signals of the clock signal terminal CLK, the first reset signal terminal RST1, the second reset signal terminal RST2, the second control signal terminal CON2, and the total reset signal terminal TRST are low-level signals. The second control signal terminal CON2 has a low-level signal, the twentieth transistor T20 is turned off, and the signal of the signal input terminal IN is not pulled down. Working processes of the first transistor T1 to the eighteenth transistor T18 are the same as working processes of the first transistor T1 to the eighteenth transistor T18 of the shift register provided in FIG. 17 in the first phase P11, which will not be repeated here.

In a second phase P22, that is, an output phase, the second control signal terminal CON2 and the clock signal terminal CLK have high-level signals, and signals of the first reset signal terminal RST1, the second reset signal terminal RST2, and the total reset signal terminal TRST are low-level signals. A signal of the second control signal terminal CON2 is a high-level signal, the twentieth transistor T20 is turned on, the signal of the signal input terminal IN is pulled up, the first transistor T1 is turned on, the high-level signal of the second power supply terminal V2 or the signal input terminal IN is continuously written into the pull-up node PU, and working processes of the second transistor T2 to the eighteenth transistor T18 are the same as working processes of the second transistor T2 to the eighteenth transistor T18 of the shift register provided in FIG. 17 in the second phase P12, which will not be repeated here.

In the second phase, since the signal of the signal input terminal IN is a high-level signal, the first transistor T1 is not in a negative bias state in the second phase P22, and no drift occurs in characteristics of the first transistor T1.

In a third phase P23, that is, a reset phase, the first reset signal terminal RST1 and the second reset signal terminal RST2 have high-level signals, and signals of the signal input terminal IN, the second control signal terminal CON2, the total reset signal terminal TRST, and the clock signal terminal CLK are low-level signals. A signal of the second control signal terminal CON2 is a low-level signal, the twentieth transistor T20 is turned off, and the signal of the second control signal terminal CON2 will not be written into the signal input terminal IN. Since a signal input terminal IN of a current-stage shift register is electrically connected with a second output terminal OUT2 of a previous-stage shift register, and a signal of the second output terminal OUT2 of the previous-stage shift register is a low-level signal in this phase, a signal of the signal input terminal IN of the current-stage shift register will be pulled low in this phase, and is a low-level signal. Working processes of the first transistor T1 to the eighteenth transistor T18 are the same as working processes of the first transistor T1 to the eighteenth transistor T18 of the shift register provided in FIG. 17 in the third phase P13.

In the third phase P23, since a second output terminal OUT2 of the current-stage shift register is electrically connected with a signal input terminal IN of a next-stage shift register, and the signal input terminal IN of the next-stage shift register has a high-level signal in this phase, the second output terminal OUT2 of the current-stage shift register has a high-level signal in this phase.

In a fourth phase P24, that is, a first noise reduction phase, signals of the first reset signal terminal RST1, the second reset signal terminal RST2, and the clock signal terminal CLK are high-level signals, and the signal input terminal IN, the second control signal terminal CON2, and the total reset signal terminal TRST have low-level signals. A signal of the second control signal terminal CON2 is a low-level signal, the twentieth transistor T20 is turned off, a signal of the second power supply terminal V2 or the signal input terminal IN cannot be written into the pull-up node PU, a signal of the pull-up node PU holds a low-level signal of a previous phase, signals of the first reset signal terminal RST1 and the second reset signal terminal RST2 are high-level signals, the fifth transistor T5 and the sixth transistor T6 are turned on, and working processes of the first transistor T1 to the fourth transistor T4, and the seventh transistor T7 to the eighteenth transistor T18 are the same as working processes of the first transistor T1 to the fourth transistor T4, and the seventh transistor T7 to the eighteenth transistor T18 of the shift register provided in FIG. 17 in the fourth phase P14.

In a fifth phase P25, that is, a second noise reduction phase, the clock signal terminal CLK, the signal input terminal IN, the first reset signal terminal RST1, the second reset signal terminal RST2, the second control signal terminal CON2, and the total reset signal terminal TRST have low-level signals. A signal of the second control signal terminal CON2 is a low-level signal, the twentieth transistor T20 is turned off, the signal of the second power supply terminal V2 or the signal input terminal IN cannot be written into the pull-up node PU, a signal of the pull-up node PU holds a low-level signal of a previous phase, and working processes of the first transistor T1 to the eighteenth transistor T18 are the same as working processes of the first transistor T1 to the eighteenth transistor T18 of the shift register provided in FIG. 17 in the fifth phase P15, which will not be repeated here.

The working process of the shift register unit further includes a plurality of fourth phases P24 and a plurality of fifth phases P25, and a fourth phase P24 and a fifth phase P25 are alternately operated.

The fourth phase P24 and the fifth phase P25 may ensure that signals of the pull-up node PU, the first output terminal OUT1, and the second output terminal OUT2 of the shift register are continuously low-level signals, and may reduce a noise of the shift register and improve reliability of the shift register.

A working process of the shift register provided in FIG. 18 in the non-display phase may include following phases.

In a sixth phase P26, a signal of the total reset signal terminal TRST is a high-level signal, and the signal input terminal IN, the first reset signal terminal RST1, the second reset signal terminal RST2, and the second control signal terminal CON2 have low-level signals. A signal of the total reset signal terminal TRST is a high-level signal, the fourth transistor T4 is turned on, and a low-level signal of the first power supply terminal V1 is written into the pull-up node PU to pull down a signal of the pull-up node PU.

Compared with the shift register provided in FIG. 18, the shift register provided in FIG. 21 has the twenty-first transistor T21. In conjunction with FIGS. 21 and 24, a working process of the shift register provided in FIG. 21 in the display phase may include following phases.

Compared with the shift register provided in FIG. 18 in the first phase P21, the shift register provided in FIG. 21 in the first phase P21 has same working processes of the first transistor T1 to the eighteenth transistor T18, and the twentieth transistor T20, except that the first transistor T1 is turned on, the high-level signal of the second power supply terminal V2 or the signal input terminal IN is written into the control node N, the twenty-first transistor T21 is turned on, a high-level signal of the control node N is written into the pull-up node PU, and the pull-up node PU is pulled up by the signal of the control node N.

Compared with the shift register provided in FIG. 18 in the second phase P22, the shift register provided in FIG. 21 in the second phase P22 has same working processes of the first transistor T1 to the eighteenth transistor T18, and the twentieth transistor T20, except that a signal of the control node N holds a high-level signal of a previous phase, and the twenty-first transistor T21 is continuously turned on.

Compared with the shift register provided in FIG. 18, in the shift register provided in FIG. 21, due to presence of the twenty-first transistor T21, a voltage value of the signal of the control node N in the second phase is smaller than a voltage value of the signal of the pull-up node PU, that is, an absolute value of a difference value between a voltage value of the signal of the signal input terminal and a voltage value of the signal of the control node N in the shift register provided in FIG. 21 is smaller than an absolute value of a difference value between a voltage value of the signal of the signal input terminal and a voltage value of the signal of the pull-up node in the shift register provided in FIG. 18, that is, a degree of negative bias of the first transistor in the shift register provided in FIG. 21 is smaller than a degree of negative bias of the first transistor in the shift register provided in FIG. 18, and the shift register provided in FIG. 21 may prevent characteristic drift of the first transistor to some extent.

The working process of the shift register provided in FIG. 21 in the third phase P23 is the same as the working process of the shift register provided in FIG. 18 in the third phase P23, which will not be repeated here.

The working process of the shift register provided in FIG. 21 in the fourth phase P24 is the same as the working process of the shift register provided in FIG. 18 in the fourth phase P24, which will not be repeated here.

The working process of the shift register provided in FIG. 21 in the fifth phase P25 is the same as the working process of the shift register provided in FIG. 18 in the fifth phase P25, which will not be repeated here.

The working process of the shift register provided in FIG. 21 in the sixth phase P26 of the non-display phase is the same as the working process of the shift register provided in FIG. 18 in the sixth phase P26 of the non-display phase, which will not be repeated here.

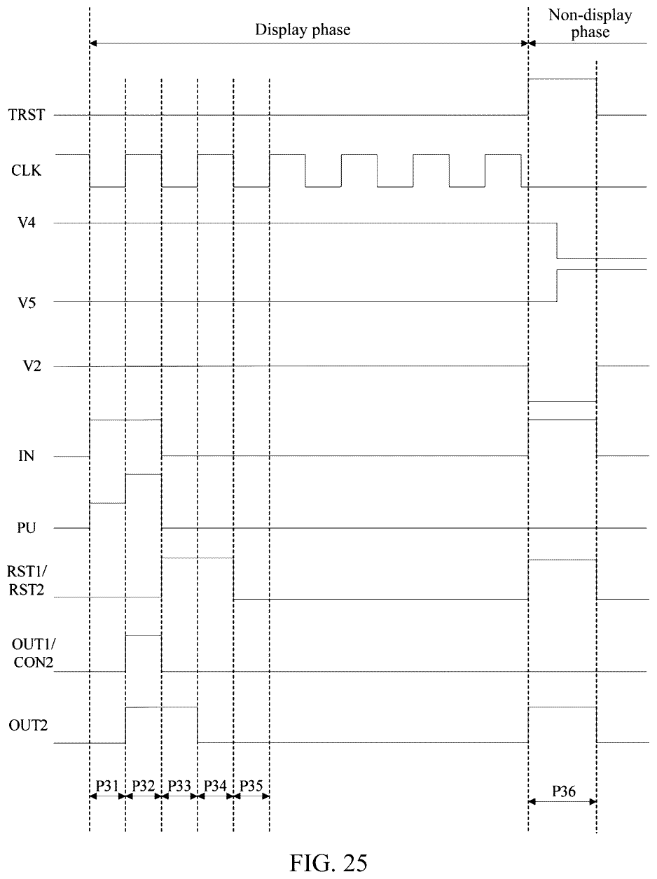

FIG. 25 is a working timing diagram of the shift register provided in FIG. 19 and FIG. 22. FIG. 25 is illustrated by taking a case in which all transistors in a shift register unit are N-type transistors as an example.

In an exemplary implementation mode, as shown in FIG. 23, when a signal of the total reset signal terminal TRST is an active level signal, a signal of the second power supply terminal V2 is a low-level signal, and when a signal of the total reset signal terminal TRST is an inactive level signal, a signal of the second power supply terminal V2 is a high-level signal.

In conjunction with FIGS. 19 and 25, a working process of the shift register provided in FIG. 19 in the display phase may include following phases.

In a first phase P31, that is, an input phase, a signal of the signal input terminal IN is a high-level signal, and signals of the clock signal terminal CLK, the first reset signal terminal RST1, the second reset signal terminal RST2, the first control signal terminal CON1, the second control signal terminal CON2, and the total reset signal terminal TRST are low-level signals. The first control signal terminal CON1 has a low-level signal, the nineteenth transistor T19 is turned off, the second control signal terminal CON2 has a low-level signal, the twentieth transistor T20 is turned off, and the signal of the signal input terminal IN is not pulled down. Working processes of the first transistor T1 to the eighteenth transistor T18 are the same as working processes of the first transistor T1 to the eighteenth transistor T18 of the shift register provided in FIG. 18 in the first phase P21, which will not be repeated here.

In a second phase P32, that is, an output phase, signals of the second control signal terminal CON2 and the clock signal terminal CLK are high-level signals, and signals of the first control signal terminal CON1, the first reset signal terminal RST1, the second reset signal terminal RST2, and the total reset signal terminal TRST are low-level signals. A signal of the first control signal terminal CON1 is a low-level signal, the nineteenth transistor T19 is turned off, a signal of the second control signal terminal CON2 is a high-level signal, the twentieth transistor T20 is turned on, and the signal of the signal input terminal IN is pulled up. Working processes of the first transistor T1 to the eighteenth transistor T18 are the same as working processes of the first transistor T1 to the eighteenth transistor T18 of the shift register provided in FIG. 18 in the second phase P22, which will not be repeated here.

In the second phase, since the signal of the signal input terminal IN is a high-level signal, the first transistor T1 is not in a negative bias state in the second phase P22, and no drift occurs in characteristics of the first transistor T1.

In a third phase P33, that is, a reset phase, signals of the first reset signal terminal RST1 and the second reset signal terminal RST2 are high-level signals, and signals of the first control signal terminal CON1, the second control signal terminal CON2, the total reset signal terminal TRST, and the clock signal terminal CLK are low-level signals. A signal of the first control signal terminal CON1 is a low-level signal, the nineteenth transistor T19 is turned off, a signal of the second control signal terminal CON2 is a low-level signal, the twentieth transistor T20 is turned off, and the signal of the signal input terminal IN is pulled down by a signal of a second output terminal of a previous-stage shift register. Working processes of the first transistor T1 to the eighteenth transistor T18 are the same as working processes of the first transistor T1 to the eighteenth transistor T18 of the shift register provided in FIG. 18 in the third phase P23, which will not be repeated here.

In a fourth phase P34, that is, a first noise reduction phase, signals of the clock signal terminal CLK, the first reset signal terminal RST1, and the second reset signal terminal RST2 are high-level signals, and signals of the signal input terminal IN, the first control signal terminal CON1, the second control signal terminal CON2, and the total reset signal terminal TRST are low-level signals. A signal of the first control signal terminal CON1 is a low-level signal, the nineteenth transistor T19 is turned off, a signal of the second control signal terminal CON2 is a low-level signal, the twentieth transistor T20 is turned off, the signal of the second power supply terminal V2 or the signal input terminal IN cannot be written into the pull-up node PU, a signal of the pull-up node PU holds a low-level signal of a previous phase, and working processes of the first transistor T1 to the eighteenth transistor T18 are the same as working processes of the first transistor T1 to the eighteenth transistor T18 of the shift register provided in FIG. 18 in the fourth phase P24, which will not be repeated here.

In a fifth phase P35, that is, a second noise reduction phase, signals of the clock signal terminal CLK, the signal input terminal IN, the first reset signal terminal RST1, the second reset signal terminal RST2, the first control signal terminal CON1, the second control signal terminal CON2, and the total reset signal terminal TRST are low-level signals. A signal of the first control signal terminal CON1 is a low-level signal, the nineteenth transistor T19 is turned off, a signal of the second control signal terminal CON2 is a low-level signal, the twentieth transistor T20 is turned off, the signal of the second power supply terminal V2 or the signal input terminal IN cannot be written into the pull-up node PU, a signal of the pull-up node PU holds a low-level signal of a previous phase, and working processes of the first transistor T1 to the eighteenth transistor T18 are the same as working processes of the first transistor T1 to the eighteenth transistor T18 of the shift register provided in FIG. 18 in the fifth phase P25, which will not be repeated here.

The working process of the shift register unit further includes a plurality of fourth phases P34 and a plurality of fifth phases P35, and a fourth phase P34 and a fifth phase P35 are alternately operated.

The fourth phase P34 and the fifth phase P35 may ensure that signals of the pull-up node PU, the first output terminal OUT1, and the second output terminal OUT2 of the shift register are continuously low-level signals, and may reduce a noise of the shift register and improve reliability of the shift register.

A working process of the shift register provided in FIG. 19 in the non-display phase may include following phases.

In a sixth phase P36, signals of the total reset signal terminal TRST and the first control signal terminal CON1 are high-level signals, and the signal input terminal IN, the first reset signal terminal RST1, the second reset signal terminal RST2, and the second control signal terminal CON2 have low-level signals. A signal of the second control signal terminal CON2 is a low-level signal, the twentieth transistor T20 is turned off, and working processes of the first transistor T1 to the nineteenth transistor T19 are the same as those of the shift register provided in FIG. 17 in the sixth phase P16, which will not be repeated here.

Compared with the shift register provided in FIG. 19, the shift register provided in FIG. 22 has the twenty-first transistor T21. In conjunction with FIGS. 22 and 25, a working process of the shift register provided in FIG. 22 in the display phase may include following phases.

Compared with the shift register provided in FIG. 19 in the first phase P31, the shift register provided in FIG. 22 in the first phase P31 has same working processes of the first transistor T1 to the twentieth transistor T20, except that the first transistor T1 is turned on, the high-level signal of the second power supply terminal V2 or the signal input terminal IN is written into the control node N, the twenty-first transistor T21 is turned on, a high-level signal of the control node N is written into the pull-up node PU, and the pull-up node PU is pulled up by the signal of the control node N.

Compared with the shift register provided in FIG. 19 in the second phase P32, the shift register provided in FIG. 22 in the second phase P32 has same working processes of the first transistor T1 to the twentieth transistor T20, except that a signal of the control node N holds a high-level signal of a previous phase, and the twenty-first transistor T21 is continuously turned on.

Compared with the shift register provided in FIG. 19, in the shift register provided in FIG. 22, due to presence of the twenty-first transistor T21, a voltage value of the signal of the control node N in the second phase is smaller than a voltage value of the signal of the pull-up node PU, that is, an absolute value of a difference value between a voltage value of the signal of the signal input terminal and a voltage value of the signal of the control node N in the shift register provided in FIG. 22 is smaller than an absolute value of a difference value between a voltage value of the signal of the signal input terminal and a voltage value of the signal of the pull-up node in the shift register provided in FIG. 19, that is, a degree of negative bias of the first transistor in the shift register provided in FIG. 22 is smaller than a degree of negative bias of the first transistor in the shift register provided in FIG. 19, and the shift register provided in FIG. 22 may prevent characteristic drift of the first transistor to some extent.

The working process of the shift register provided in FIG. 22 in the third phase P33 is the same as the working process of the shift register provided in FIG. 19 in the third phase P33, which will not be repeated here.

Compared with the shift register provided in FIG. 19, in the shift register provided in FIG. 22, due to presence of the twenty-first transistor T21, a voltage value of the signal of the control node N in the second phase is smaller than a voltage value of the signal of the pull-up node PU, that is, an absolute value of a difference value between a voltage value of the signal of the signal input terminal and a voltage value of the signal of the control node N in the shift register provided in FIG. 22 is smaller than an absolute value of a difference value between a voltage value of the signal of the signal input terminal and a voltage value of the signal of the pull-up node in the shift register provided in FIG. 19, that is, a degree of negative bias of the first transistor in the shift register provided in FIG. 22 is smaller than a degree of negative bias of the first transistor in the shift register provided in FIG. 19, and the shift register provided in FIG. 22 may prevent characteristic drift of the first transistor to some extent.

The working process of the shift register provided in FIG. 22 in the fourth phase P34 is the same as the working process of the shift register provided in FIG. 19 in the fourth phase P34, which will not be repeated here.

The working process of the shift register provided in FIG. 22 in the fifth phase P35 is the same as the working process of the shift register provided in FIG. 19 in the fifth phase P35, which will not be repeated here.

A working process of the shift register provided in FIG. 22 in the non-display phase may include following phases.

In a sixth phase P36, signals of the total reset signal terminal TRST and the first control signal terminal CON1 are high-level signals, a signal of the second control signal terminal CON2 is a low-level signal, the signal of the second control signal terminal CON2 is a low-level signal, the twentieth transistor T20 is turned off, and working processes of the first transistor T1 to the nineteenth transistor T19 are the same as working processes of the first transistor T1 to the nineteenth transistor T19 in the shift register provided in FIG. 19, which will not be repeated here.

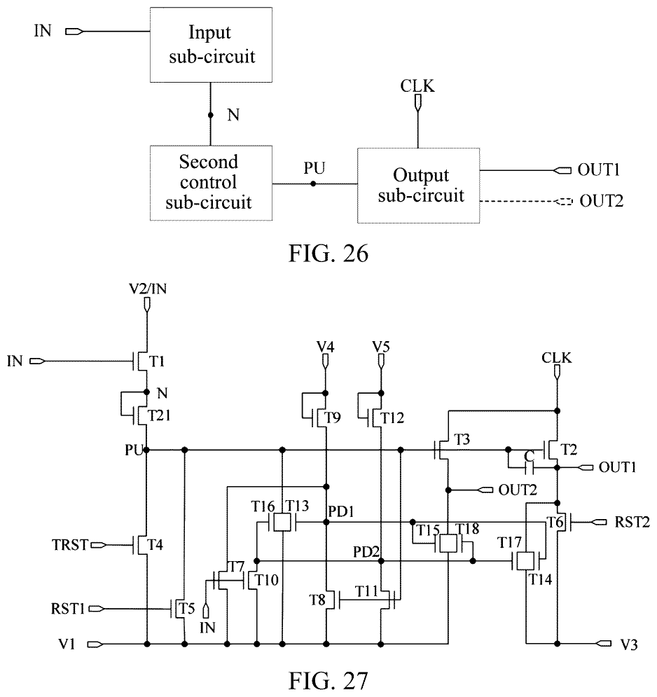

An embodiment of the present disclosure also provides a shift register, and FIG. 26 is a schematic diagram of a structure of another shift register according to an embodiment of the present disclosure. As shown in FIG. 26, the shift register according to the embodiment of the present disclosure may include an input sub-circuit, an output sub-circuit, and a second control sub-circuit. Among them, the input sub-circuit is electrically connected with a signal input terminal IN and a control node N, respectively, and is configured to provide a signal to the control node N under control of the signal input terminal IN; the second control sub-circuit is electrically connected with the control node N and a pull-up node PU, respectively, and is configured to provide a signal of the control node N to the pull-up node PU under control of the signal of the control node N; the output sub-circuit is electrically connected with a first output terminal OUT1, the pull-up node PU, and a clock signal terminal CLK, respectively, and is configured to provide a signal of the clock signal terminal CLK to the first output terminal OUT1 under control of a signal of the pull-up node PU.

In the present disclosure, an arrangement of the second control sub-circuit may play a role of voltage division, so that a signal of the control node N in an output phase may be smaller than a signal of the pull-up node PU, thereby reducing a degree of negative bias of some transistors in the input sub-circuit, and improving reliability of the shift register.

FIG. 27 is an equivalent circuit diagram of a shift register according to another exemplary embodiment. As shown in FIG. 27, the shift register may further include a first reset sub-circuit, a second reset sub-circuit, and a noise reduction sub-circuit; the input sub-circuit includes a first transistor T1; the output sub-circuit includes a second transistor T2, a third transistor T3, and a capacitor; the second control sub-circuit includes a twenty-first transistor T21; the first reset sub-circuit includes a fourth transistor T4; the second reset sub-circuit includes a fifth transistor T5 and a sixth transistor T6; the noise reduction sub-circuit includes a seventh transistor T7 to an eighteenth transistor T18. Among them, a control electrode of the first transistor T1 is electrically connected with a signal input terminal IN, a first electrode of the first transistor T1 is electrically connected with the signal input terminal IN or a second power supply terminal V2, and a second electrode of the first transistor T1 is electrically connected with a control node; a control electrode of the second transistor T2 is electrically connected with a pull-up node PU, a first electrode of the second transistor T2 is electrically connected with a clock signal terminal CLK, and a second electrode of the second transistor T2 is electrically connected with a first output terminal OUT1; a control electrode of the third transistor T3 is electrically connected with the pull-up node PU, a first electrode of the third transistor T3 is electrically connected with the clock signal terminal CLK, and a second electrode of the third transistor T3 is electrically connected with a second output terminal OUT2; a first terminal of the capacitor C is electrically connected with the pull-up node PU, and a second terminal of the capacitor C is electrically connected with the first output terminal OUT1; a control electrode of the fourth transistor T4 is electrically connected with a total reset signal terminal TRST, a first electrode of the fourth transistor T4 is electrically connected with the pull-up node PU, and a second electrode of the fourth transistor T4 is electrically connected with a first power supply terminal V1; a control electrode of the fifth transistor T5 is electrically connected with a first reset signal terminal RST1, a first electrode of the fifth transistor T5 is electrically connected with the pull-up node PU, and a second electrode of the fifth transistor T5 is electrically connected with the first power supply terminal V1; a control electrode of the sixth transistor T6 is electrically connected with a second reset signal terminal RST2, a first electrode of the sixth transistor T6 is electrically connected with the first output terminal OUT1, and a second electrode of the sixth transistor T6 is electrically connected with the first power supply terminal V1; a control electrode of the seventh transistor T7 is electrically connected with the signal input terminal IN, a first electrode of the seventh transistor T7 is electrically connected with a first pull-down node PD1, and a second electrode of the seventh transistor T7 is electrically connected with the first power supply terminal V1; a control electrode of the eighth transistor T8 is electrically connected with the pull-up node PU, a first electrode of the eighth transistor T8 is electrically connected with the first pull-down node PD1, and a second electrode of the eighth transistor T8 is electrically connected with the first power supply terminal V1; a control electrode and a first electrode of the ninth transistor T9 are respectively electrically connected with a fourth power supply terminal V4, and a second electrode of the ninth transistor T9 is electrically connected with the first pull-down node PD1; a control electrode of the tenth transistor T10 is electrically connected with the signal input terminal IN, a first electrode of the tenth transistor T10 is electrically connected with a second pull-down node PD2, and a second electrode of the tenth transistor T10 is electrically connected with the first power supply terminal V1; a control electrode of the eleventh transistor T11 is electrically connected with the pull-up node PU, a first electrode of the eleventh transistor T11 is electrically connected with the second pull-down node PD2, and a second electrode of the eleventh transistor T11 is electrically connected with the first power supply terminal V1; a control electrode and a first electrode of the twelfth transistor T12 are electrically connected with a fifth power supply terminal V5, respectively, and a second electrode of the twelfth transistor T12 is electrically connected with the second pull-down node PD2; a control electrode of the thirteenth transistor T13 is electrically connected with the first pull-down node PD1, a first electrode of the thirteenth transistor T13 is electrically connected with the pull-up node PU, and a second electrode of the thirteenth transistor T13 is electrically connected with the first power supply terminal V1; a control electrode of the fourteenth transistor T14 is electrically connected with the first pull-down node PD1, a first electrode of the fourteenth transistor T14 is electrically connected with the first output terminal OUT1, and a second electrode of the fourteenth transistor T14 is electrically connected with a third power supply terminal V3; a control electrode of the fifteenth transistor T15 is electrically connected with the first pull-down node PD1, a first electrode of the fifteenth transistor T15 is electrically connected with the second output terminal OUT2, and a second electrode of the fifteenth transistor T15 is electrically connected with the first power supply terminal V1; a control electrode of the sixteenth transistor T16 is electrically connected with the second pull-down node PD2, a first electrode of the sixteenth transistor T16 is electrically connected with the pull-up node PU, and a second electrode of the sixteenth transistor T16 is electrically connected with the first power supply terminal V1; a control electrode of the seventeenth transistor T17 is electrically connected with the second pull-down node PD2, a first electrode of the seventeenth transistor T17 is electrically connected with the first output terminal OUT1, and a second electrode of the seventeenth transistor T17 is electrically connected with the third power supply terminal V3; a control electrode of the eighteenth transistor T18 is electrically connected with the second pull-down node PD2, a first electrode of the eighteenth transistor T18 is electrically connected with the second output terminal OUT2, and a second electrode of the eighteenth transistor T18 is electrically connected with the first power supply terminal V1; a control electrode and a first electrode of the twenty-first transistor T21 are respectively electrically connected with the control node, and a second electrode of the twenty-first transistor T21 is electrically connected with the pull-up node PU.

In an exemplary implementation mode, transistors may be divided into N-type transistors and P-type transistors according to characteristics of the transistors. When a transistor is a P-type transistor, its turn-on voltage is a low-level voltage (e.g., 0 V, −5 V, −10 V, or another suitable voltage), and its turn-off voltage is a high-level voltage (e.g., 5 V, 10 V, or another suitable voltage). When a transistor is an N-type transistor, its turn-on voltage is a high-level voltage (e.g., 5 V, 10 V, or another suitable voltage), and its turn-off voltage is a low-level voltage (e.g., 0V, −5 V, −10 V, or another suitable voltage).

In an exemplary implementation mode, all transistors in the shift register are N-type transistors. For example, all transistors in the shift register may be metal oxide transistors. Since a metal oxide transistor has a higher mobility and a low leakage current, all transistors in the shift register are metal oxide transistors, which may increase a refresh rate of a display product, realize high-frequency display, and also realize low-frequency display, thereby reducing power consumption.

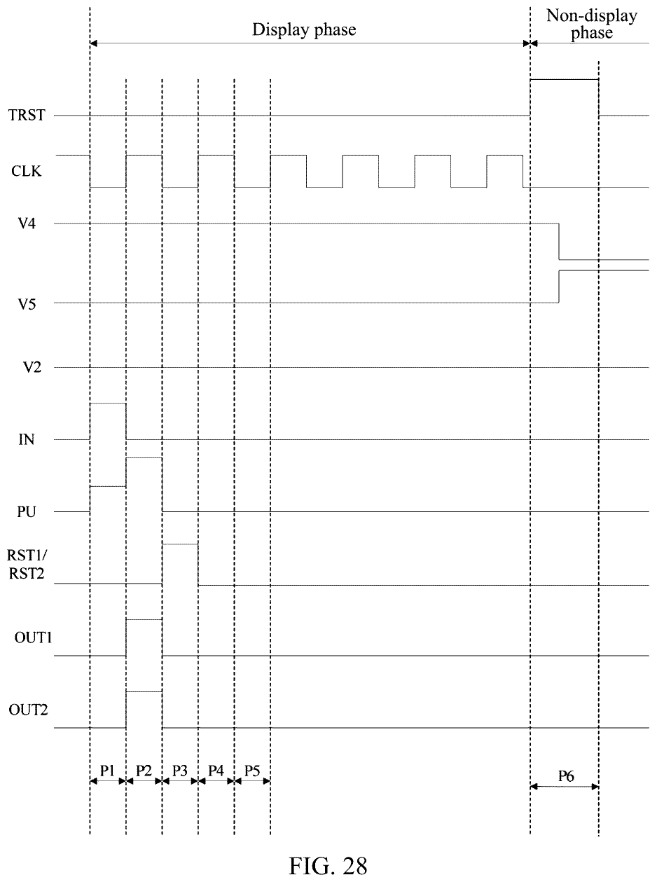

FIG. 28 is a working timing diagram of the shift register provided in FIG. 27. FIG. 28 is illustrated by taking a case in which all transistors in the shift register unit are N-type transistors as an example.

In conjunction with FIGS. 27 and 28, a working process of the shift register provided in FIG. 27 in the display phase may include following phases.

In a first phase P1, that is, an input phase, a signal of the signal input terminal IN is a high-level signal, and signals of the clock signal terminal CLK, the first reset signal terminal RST1, the second reset signal terminal RST2, and the total reset signal terminal TRST are low-level signals. The signal of the signal input terminal IN is a high-level signal, the first transistor T1 is turned on, a high-level signal of the second power supply terminal V2 or the signal input terminal IN is written into the control node N, the twenty-first transistor T21 is turned on, the high-level signal of the control node N is written into the pull-up node PU, the pull-up node PU is pulled up, the seventh transistor T7 and the tenth transistor T10 are turned on, a low-level signal of the first power supply terminal V1 is written into the first pull-down node PD1 and the second pull-down node PD2, a signal of the pull-up node PU is a high-level signal, the second transistor T2 and the third transistor T3 are turned on, a low-level signal of the clock signal terminal CLK is written into the first output terminal OUT1 and the second output terminal OUT2, the eighth transistor T8 and the eleventh transistor T11 are turned on, and the low-level signal of the first power supply terminal V1 is continuously written into the first pull-down node PD1 and the second pull-down node PD2. Signals of the first pull-down node PD1 and the second pull-down node PD2 are continuously low-level signals, and the thirteenth transistor T13 to the eighteenth transistor T18 are turned off. In this phase, the signal of the pull-up node PU is a high-level signal, and signals of the first pull-down node PD1, the second pull-down node PD2, the first output terminal OUT1, and the second output terminal OUT2 are low-level signals.

In the first phase, when the shift register is in a first display frame, the ninth transistor T9 is turned on and the twelfth transistor T12 is turned off. Although the ninth transistor T9 is turned on, a high-level signal of the fourth power supply terminal V4 will pull up a signal of the first pull-down node PD1, but the signal of the first pull-down node PD1 is still pulled down to a low-level signal since the seventh transistor T7, the eighth transistor T8, the tenth transistor T10, and the eleventh transistor T11 are continuously turned on. Similarly, when the shift register is in a second display frame, the ninth transistor T9 is turned off and the twelfth transistor T12 is turned on. Although the twelfth transistor T12 is turned on, a high-level signal of the fifth power supply terminal V5 will pull up a signal of the second pull-down node PD2, but the signal of the second pull-down node PD2 is still pulled down to a low-level signal since the seventh transistor T7, the eighth transistor T8, the tenth transistor T10, and the eleventh transistor T11 are continuously turned on. Regardless of whether the shift register is in the first display frame or the second display frame, the first pull-down node PD1 and the second pull-down node PD2 continue to have low-level signals in the first phase.

In a second phase P2, i.e., an output phase, signals of the signal input terminal IN, the first reset signal terminal RST1, the second reset signal terminal RST2, and the total reset signal terminal TRST are low-level signals, and the clock signal terminal CLK has a high-level signal. A signal of the signal input terminal IN is a low-level signal, the first transistor T1, the seventh transistor T7, and the tenth transistor T10 are turned off. A signal of the control node N holds a high-level signal of a previous phase, the twenty-first transistor T21 is continuously turned on. Under a bootstrap action of the capacitor C, a signal of the pull-up node PU is pulled up, the second transistor T2 and the third transistor T3 are turned on, the high-level signal of the clock signal terminal CLK is written into the first output terminal OUT1 and the second output terminal OUT2, the eighth transistor T8 and the eleventh transistor T11 are turned on, a low-level signal of the first power supply terminal V1 is continuously written into the first pull-down node PD1 and the second pull-down node PD2, and the first pull-down node PD1 and the second pull-down node PD2 continue to have low-level signals, and the thirteenth transistor T13, the fourteenth transistor T14, the fifteenth transistor T15, the sixteenth transistor T16, the seventeenth transistor T17, and the eighteenth transistor T18 are turned off. In this phase, signals of the pull-up node PU, the first output terminal OUT1, and the second output terminal OUT2 are high-level signals, and signals of the first pull-down node PD1 and the second pull-down node PD2 are low-level signals.

In the second phase, when the shift register is in a first display frame, the ninth transistor T9 is turned on and the twelfth transistor T12 is turned off. Although the ninth transistor T9 is turned on and a high-level signal of the fourth power supply terminal V4 will pull up a signal of the first pull-down node PD1, but the signal of the first pull-down node PD1 is still pulled down to a low-level signal since the eighth transistor T8 and the eleventh transistor T11 are continuously turned on. Similarly, when the shift register is in a second display frame, the ninth transistor T9 is turned off and the twelfth transistor T12 is turned on. Although the twelfth transistor T12 is turned on, a high-level signal of the fifth power supply terminal V5 will pull up a signal of the second pull-down node PD2, but the signal of the second pull-down node PD2 is still pulled down to a low-level signal since the eighth transistor T8 and the eleventh transistor T11 are continuously turned on. Regardless of whether the shift register is in the first display frame or the second display frame, the first pull-down node PD1 and the second pull-down node PD2 continue to have low-level signals in the second phase.

In the second phase, a voltage value of the signal of the signal input terminal IN is smaller than a voltage value of the signal of the control node N, so that the first transistor T1 is in a negative bias state, and a turn-on voltage of the first transistor T1 becomes smaller. In the present disclosure, due to presence of the twenty-first transistor T21, a voltage value of the signal of the control node N in the second phase is smaller than a voltage value of the signal of the pull-up node PU, that is, an absolute value of a difference value between a voltage value of the signal of the signal input terminal and a voltage value of the signal of the control node N in the shift register provided in FIG. 20 is smaller than an absolute value of a difference value between a voltage value of the signal of the signal input terminal and a voltage value of the signal of the pull-up node in the shift register in which a second control sub-circuit is not provided, that is, a degree of negative bias of the first transistor in the shift register provided in FIG. 27 is smaller than a degree of negative bias of the first transistor in the shift register in which the second control sub-circuit is not provided, and the shift register provided in FIG. 27 may prevent characteristic drift of the first transistor to some extent.

In a third phase P3, that is, a reset phase, the first reset signal terminal RST1 and the second reset signal terminal RST2 have high-level signals, and signals of the signal input terminal IN, the total reset signal terminal TRST, and the clock signal terminal CLK are low-level signals. Signals of the first reset signal terminal RST1 and the second reset signal terminal RST2 are high-level signals, the fifth transistor T5 and the sixth transistor T6 are turned on, a low-level signal of the first power supply terminal V1 is written into the pull-up node PU, the signal of the pull-up node PU is pulled down, a signal of the control node N is pulled down by the pull-up node PU, a low-level signal of the third power supply terminal V3 is written into the first output terminal OUT1, the signal of the first output terminal OUT1 is pulled down. A signal of the signal input terminal IN is a low-level signal, the first transistor T1, the seventh transistor T7, and the tenth transistor T10 are turned off, the pull-up node PU has a low-level signal, the eighth transistor T8 and the eleventh transistor T11 are turned off, and the first pull-down node PD1 and the second pull-down node PD2 are not pulled down by the low-level signal of the first power supply terminal V1. When the shift register is in a first display frame, the ninth transistor T9 is turned on, a high-level signal of the fourth power supply terminal V4 is written into the first pull-down node PD1, the thirteenth transistor T13, the fourteenth transistor T14, and the fifteenth transistor T15 are turned on, the low-level signal of the first power supply terminal V1 is written into the pull-up node PU and the second output terminal OUT2, a low-level signal of the third power supply terminal V3 is written into the first output terminal OUT1, the twelfth transistor T12 is turned off, the second pull-down node PD2 holds a low-level signal of a previous phase, and the sixteenth transistor T16, the seventeenth transistor T17, and the eighteenth transistor T18 are turned off. Or when the shift register is in a second display frame, the twelfth transistor T12 is turned on, a high-level signal of the fifth power supply terminal V5 is written into the second pull-down node PD2, the sixteenth transistor T16, the seventeenth transistor T17, and the eighteenth transistor T18 are turned on, the low-level signal of the first power supply terminal V1 is written into the pull-up node PU and the second output terminal OUT2, the low-level signal of the third power supply terminal V3 is written into the first output terminal OUT1, the ninth transistor T9 is turned off, the first pull-down node PD1 holds a low-level signal of the previous phase, and the thirteenth transistor T13, the fourteenth transistor T14, and the fifteenth transistor T15 are turned off.

In a fourth phase P4, that is, a first noise reduction phase, a signal of the clock signal terminal CLK is a high-level signal, and the signal input terminal IN, the first reset signal terminal RST1, the second reset signal terminal RST2, and the total reset signal terminal TRST have low-level signals. A signal of the signal input terminal IN is a low-level signal, the first transistor T1, the seventh transistor T7, and the tenth transistor T10 are turned off, signals of the control node N and the pull-up node PU hold low-level signal of a previous phase, the twenty-first transistor T21, the second transistor T2, the third transistor T3, the eighth transistor T8, and the eleventh transistor T11 are turned off, and the first pull-down node PD1 and the second pull-down node PD2 are not pulled down by the low-level signal of the first power supply terminal V1. When the shift register is in the first display frame, the ninth transistor T9 is turned on, the high-level signal of the fourth power supply terminal V4 is written into the first pull-down node PD1, the thirteenth transistor T13, the fourteenth transistor T14, and the fifteenth transistor T15 are turned on, the low-level signal of the first power supply terminal V1 is written into the pull-up node PU and the second output terminal OUT2, the low-level signal of the third power supply terminal V3 is written into the first output terminal OUT1, the twelfth transistor T12 is turned off, the second pull-down node PD2 holds a low-level signal of the previous phase, and the sixteenth transistor T16, the seventeenth transistor T17, and the eighteenth transistor T18 are turned off. Or when the shift register is in the second display frame, the twelfth transistor T12 is turned on, the high-level signal of the fifth power supply terminal V5 is written into the second pull-down node PD2, the sixteenth transistor T16, the seventeenth transistor T17, and the eighteenth transistor T18 are turned on, the low-level signal of the first power supply terminal V1 is written into the pull-up node PU and the second output terminal OUT2, the low-level signal of the third power supply terminal V3 is written into the first output terminal OUT1, the ninth transistor T9 is turned off, the first pull-down node PD1 holds a low-level signal of the previous phase, and the thirteenth transistor T13, the fourteenth transistor T14, and the fifteenth transistor T15 are turned off.

In a fifth phase P5, that is, a second noise reduction phase, the clock signal terminal CLK, the signal input terminal IN, the first reset signal terminal RST1, the second reset signal terminal RST2, and the total reset signal terminal TRST have low-level signals. A signal of the signal input terminal IN is a low-level signal, the first transistor T1, the seventh transistor T7, and the tenth transistor T10 are turned off, signals of the control node N and the pull-up node PU hold low-level signals of a previous phase, the twenty-first transistor T21, the second transistor T2, the third transistor T3, the eighth transistor T8, and the eleventh transistor T11 are turned off, and the first pull-down node PD1 and the second pull-down node PD2 are not pulled down by the low-level signal of the first power supply terminal V1. When the shift register is in the first display frame, the ninth transistor T9 is turned on, the high-level signal of the fourth power supply terminal V4 is written into the first pull-down node PD1, the thirteenth transistor T13, the fourteenth transistor T14, and the fifteenth transistor T15 are turned on, the low-level signal of the first power supply terminal V1 is written into the pull-up node PU and the second output terminal OUT2, the low-level signal of the third power supply terminal V3 is written into the first output terminal OUT1, the twelfth transistor T12 is turned off, the second pull-down node PD2 holds a low-level signal of the previous phase, and the sixteenth transistor T16, the seventeenth transistor T17, and the eighteenth transistor T18 are turned off. Or when the shift register is in the second display frame, the twelfth transistor T12 is turned on, the high-level signal of the fifth power supply terminal V5 is written into the second pull-down node PD2, the sixteenth transistor T16, the seventeenth transistor T17, and the eighteenth transistor T18 are turned on, the low-level signal of the first power supply terminal V1 is written into the pull-up node PU and the second output terminal OUT2, the low-level signal of the third power supply terminal V3 is written into the first output terminal OUT1, the ninth transistor T9 is turned off, the first pull-down node PD1 holds a low-level signal of the previous phase, and the thirteenth transistor T13, the fourteenth transistor T14, and the fifteenth transistor T15 are turned off.

The working process of the shift register further includes a plurality of fourth phases P4 and a plurality of fifth phases P5, and a fourth phase P4 and a fifth phase P5 are alternately operated.

The fourth phase P4 and the fifth phase P5 may ensure that signals of the pull-up node PU, the first output terminal OUT1, and the second output terminal OUT2 of the shift register are continuously low-level signals, and may reduce a noise of the shift register and improve reliability of the shift register.

As shown in FIG. 28, a working process of the shift register provided in FIG. 27 in the non-display phase may include following phases.

In a sixth phase P6, a signal of the total reset signal terminal TRST is a high-level signal, the fourth transistor T4 is turned on, and the low-level signal of the first power supply terminal V1 is written into the pull-up node PU.

An embodiment of the present disclosure also provides a drive method of a shift register configured to drive shift registers shown in FIGS. 17 to 22, and the drive method of the shift register may include following acts.

Act 110: an input sub-circuit provides a signal to a pull-up node under control of a signal of a signal input terminal.

Act 120: an output sub-circuit provides a signal of a clock signal terminal to a first output terminal under control of a signal of the pull-up node.

Act 130: a control sub-circuit provides a signal of a control signal terminal to the signal input terminal under control of a signal of the control signal terminal.

The shift register is the shift register according to any one of the foregoing embodiments, and its implementation principle and implementation effects are similar to the foregoing implementation principle and implementation effects, and will not be repeated here.

An embodiment of the present disclosure also provides a drive method of a shift register configured to drive the shift register shown in FIG. 23, and the drive method of the shift register may include following acts.

Act 210: an input sub-circuit provides a signal to a control node under control of a signal input terminal.

Act 220: a second control sub-circuit provides a signal of the control node to a pull-up node under control of the signal of the control node.

Act 230: an output sub-circuit is configured to provide a signal of a clock signal terminal to a first output terminal under control of a signal of the pull-up node.

An embodiment of the present disclosure also provides a gate drive circuit, including a plurality of cascaded shift registers.

A shift register is the shift register according to any one of the foregoing embodiments, and its implementation principle and implementation effects are similar to the foregoing implementation principle and implementation effects, and will not be repeated here.

In an exemplary implementation mode, the gate drive circuit is disposed in a display apparatus, the display apparatus is further provided with a gate line, and a shift register includes an output sub-circuit.

In an exemplary implementation mode, total reset signal terminals in all shift registers are connected with a same signal line, first power supply terminals in all shift registers are connected with a same signal line, second power supply terminals in all shift registers are connected with a same signal line, third power supply terminals in all shift registers are connected with a same signal line, fourth power supply terminals in all shift registers are connected with a same signal line, and fifth power supply terminals in all shift registers are connected with a same signal line.

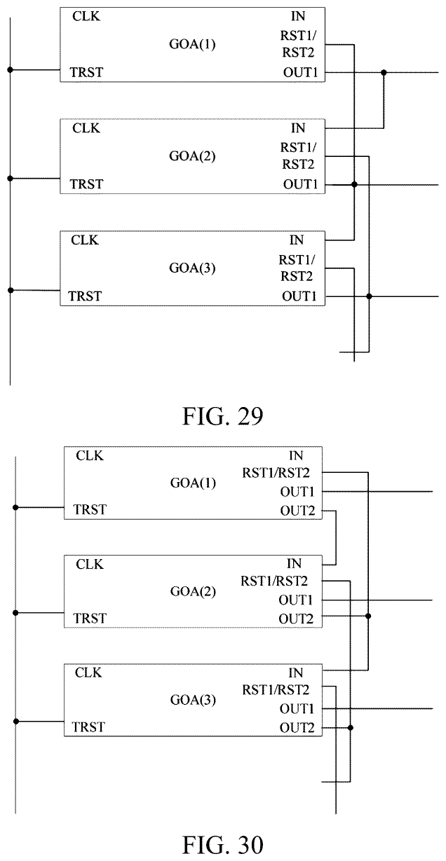

FIG. 29 is a first schematic diagram of cascade of a gate drive circuit. As shown in FIG. 29, in a state in which an output sub-circuit includes a first output terminal OUT1, a first output terminal OUT1 of any stage of shift register is electrically connected with a gate line, a first output terminal OUT1 of a current-stage shift register is electrically connected with a signal input terminal IN of a next-stage shift register, and the first output terminal OUT1 of the current-stage shift register is electrically connected with a first reset signal terminal RST1 or a second reset signal terminal RST2 of a previous-stage shift register.

FIG. 30 is a second schematic diagram of cascade of a gate drive circuit. As shown in FIG. 30, in a state in which an output sub-circuit includes a first output terminal OUT1 and a second output terminal OUT2, a first output terminal OUT1 of any stage of shift register is electrically connected with a gate line, a second output terminal OUT2 of a current-stage shift register is electrically connected with a signal input terminal IN of a next-stage shift register, and the second output terminal OUT2 of the current-stage shift register is electrically connected with a first reset signal terminal RST1 or a second reset signal terminal RST2 of a previous-stage shift register.

GOA (i) in FIGS. 29 and 30 refers to an i-th stage shift register.

An embodiment of the present disclosure also provides a display apparatus, including a gate drive circuit.

The gate drive circuit is the gate drive circuit according to any one of the foregoing embodiments, and its implementation principle and implementation effects are similar to the foregoing implementation principle and implementation effects, which will not be repeated here.

In an exemplary implementation mode, the display apparatus may be a Liquid Crystal Display (LCD for short) or an Organic Light Emitting Diode (OLED for short) display apparatus. The display apparatus may be any product or component with a display function, such as a liquid crystal panel, electronic paper, an OLED panel, an Active-Matrix Organic Light Emitting Diode (AMOLED for short) panel, a mobile phone, a tablet computer, a television, a display, a notebook computer, a digital photo frame, and a navigator.

The display apparatus may include a display substrate. The display substrate may include a plurality of pixel units disposed in a matrix, the plurality of pixel units include a first sub-pixel emitting light of a first color, a second sub-pixel emitting light of a second color, and at least one third sub-pixel emitting light of a third color, and the first sub-pixel, the second sub-pixel, and the third sub-pixel each includes a pixel drive circuit and a light emitting device. Pixel drive circuits in the first sub-pixel, the second sub-pixel, and the third sub-pixel are connected with a scan signal line, a data signal line, and a light emitting signal line respectively. A pixel drive circuit is configured to receive a data voltage transmitted by the data signal line under control of the scan signal line and the light emitting signal line, and output a corresponding current to the light emitting device. Light emitting devices in the first sub-pixel, the second sub-pixel, and the third sub-pixel are respectively connected with pixel drive circuits of sub-pixels where the light emitting devices are located. A light emitting device is configured to emit light with corresponding brightness in response to a current outputted by a pixel drive circuit of a sub-pixel where the light emitting device is located.

In an exemplary implementation mode, the first sub-pixel may be a red (R) sub-pixel emitting red light, the second sub-pixel may be a blue (B) sub-pixel emitting blue light, and the third sub-pixel may be a green (G) sub-pixel emitting green light. In an exemplary implementation mode, a sub-pixel may be in a shape of a rectangle, a rhombus, a pentagon, or a hexagon. Three sub-pixels may be arranged side by side horizontally, side by side vertically, or in a manner of a Chinese character “ [symbol] ” , the present disclosure is not limited thereto.

In an exemplary implementation mode, one pixel unit may include three sub-pixels, and the three sub-pixels may be arranged side by side horizontally, side by side vertically, or in a manner of a Chinese character “ [symbol] ”, and the present disclosure is not limited thereto.

In an exemplary implementation mode, one pixel unit may include four sub-pixels, and the four sub-pixels may be one first sub-pixel, one second sub-pixel, and two third sub-pixels. The four sub-pixels may be arranged in a manner of standing side by side horizontally, in a manner of standing side by side vertically, or in a manner of a square, which is not limited in the present disclosure.

The display substrate according to the embodiment of the present disclosure may be applied to a display product with any resolution.

The accompanying drawings of the present disclosure only involve structures involved in the embodiments of the present disclosure, and other structures may be referred to usual designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although implementation modes of the present disclosure are disclosed above, contents described are only implementation modes used for ease of understanding of the present disclosure, but not intended to limit the present disclosure. Any of those skilled in the art of the present disclosure may make any modification and variation in forms and details of implementation without departing from the spirit and scope of the present disclosure. However, the patent protection scope of the present disclosure shall still be subject to the scope defined in the appended claims.

1. A shift register, comprising an input sub-circuit, an output sub-circuit, and a first control sub-circuit; wherein
the input sub-circuit is electrically connected with a signal input terminal and a pull-up node, respectively, and is configured to provide a signal to the pull-up node under control of a signal of the signal input terminal;
the output sub-circuit is electrically connected with a first output terminal, the pull-up node, and a clock signal terminal, respectively, and is configured to provide a signal of the clock signal terminal to the first output terminal under control of a signal of the pull-up node; and
the first control sub-circuit is electrically connected with a control signal terminal and the signal input terminal, respectively, and is configured to provide a signal of the control signal terminal to the signal input terminal under control of the signal of the control signal terminal.

2. The shift register according to claim 1, further comprising a first reset sub-circuit; wherein
the first reset sub-circuit is electrically connected with a total reset signal terminal, the pull-up node, and a first power supply terminal, respectively, and is configured to provide a signal of the first power supply terminal to the pull-up node under control of the total reset signal terminal; and
the total reset signal terminal has an active level signal in part of time periods of a non-display phase and an inactive level signal in a display phase.

3. The shift register according to claim 1, wherein the control signal terminal comprises at least one of a first control signal terminal and a second control signal terminal; and
the first control signal terminal is electrically connected with a total reset signal terminal, and the second control signal terminal is electrically connected with the first output terminal.

4. The shift register according to claim 3, wherein in a state in which the control signal terminal comprises the first control signal terminal, the first control sub-circuit comprises a nineteenth transistor; and
a control electrode and a first electrode of the nineteenth transistor are respectively electrically connected with the first control signal terminal, and a second electrode of the nineteenth transistor is electrically connected with the signal input terminal-;
or,
wherein in a state in which the control signal terminal comprises the second control signal terminal, the first control sub-circuit comprises a twentieth transistor; and
a control electrode and a first electrode of the twentieth transistor are respectively electrically connected with the second control signal terminal, and a second electrode of the twentieth transistor is electrically connected with the signal input terminal;
or,
wherein in a state in which the control signal terminal comprises the first control signal terminal and the second control signal terminal, the control sub-circuit comprises a nineteenth transistor and a twentieth transistor;
a control electrode and a first electrode of the nineteenth transistor are respectively electrically connected with the first control signal terminal, and a second electrode of the nineteenth transistor is electrically connected with the signal input terminal; and
a control electrode and a first electrode of the twentieth transistor are respectively electrically connected with the second control signal terminal, and a second electrode of the twentieth transistor is electrically connected with the signal input terminal.

5-6. (canceled)

7. The shift register according to claim 1, wherein the input sub-circuit comprises a first transistor; and
a control electrode of the first transistor is electrically connected with the signal input terminal, a first electrode of the first transistor is electrically connected with the signal input terminal or a second power supply terminal, and a second electrode of the first transistor is electrically connected with the pull-up node;
or,
wherein the input sub-circuit comprises a first transistor and a twenty-first transistor;
a control electrode of the first transistor is electrically connected with the signal input terminal, a first electrode of the first transistor is electrically connected with the signal input terminal or a second power supply terminal, and a second electrode of the first transistor is electrically connected with a control node; and
a control electrode and a first electrode of the twenty-first transistor are respectively electrically connected with the control node, and a second electrode of the twenty-first transistor is electrically connected with the pull-up node;
or,
wherein the output sub-circuit comprises a second transistor and a capacitor;
a control electrode of the second transistor is electrically connected with the pull-up node, a first electrode of the second transistor is electrically connected with the clock signal terminal, and a second electrode of the second transistor is electrically connected with the first output terminal; and
a first terminal of the capacitor is electrically connected with the pull-up node, and a second terminal of the capacitor is electrically connected with the first output terminal.

8-9. (canceled)

10. That shift register according to claim 1, wherein the output sub-circuit is further electrically connected with a second output terminal and is configured to provide a signal of the clock signal terminal to the second output terminal under control of the signal of the pull-up node.

11. The shift register according to claim 10, wherein the output sub-circuit comprises a second transistor, a third transistor, and a capacitor;
a control electrode of the second transistor is electrically connected with the pull-up node, a first electrode of the second transistor is electrically connected with the clock signal terminal, and a second electrode of the second transistor is electrically connected with the first output terminal;
a control electrode of the third transistor is electrically connected with the pull-up node, a first electrode of the third transistor is electrically connected with the clock signal terminal, and a second electrode of the third transistor is electrically connected with the second output terminal; and
a first terminal of the capacitor is electrically connected with the pull-up node, and a second terminal of the capacitor is electrically connected with the first output terminal.

12. (canceled)

13. The shift register according to claim 1, further comprising a second reset sub-circuit; wherein
the second reset sub-circuit is electrically connected with a first reset signal terminal, a second reset signal terminal, the pull-up node, the first output terminal, a first power supply terminal, and a third power supply terminal, respectively, and is configured to provide a signal of the first power supply terminal to the pull-up node and provide a signal of the third power supply terminal to the first output terminal under control of signals of the first reset signal terminal and the second reset signal terminal;
an absolute value of a voltage of the signal of the first power supply terminal is greater than an absolute value of a voltage of the signal of the third power supply terminal; and
the first reset signal terminal and the second reset signal terminal have inactive level signals in a non-display phase and an output phase, and have active level signals in part of time periods of a non-output phase.

14. The shift register according to claim 13, wherein the second reset sub-circuit comprises a fifth transistor and a sixth transistor;
a control electrode of the fifth transistor is electrically connected with the first reset signal terminal, a first electrode of the fifth transistor is electrically connected with the pull-up node, and a second electrode of the fifth transistor is electrically connected with the first power supply terminal; and
a control electrode of the sixth transistor is electrically connected with the second reset signal terminal, a first electrode of the sixth transistor is electrically connected with the first output terminal, and a second electrode of the sixth transistor is electrically connected with the third power supply terminal.

15. The shift register according to claim 10, further comprising a noise reduction sub-circuit, wherein the noise reduction sub-circuit comprises at least one of a first noise reduction sub-circuit and a second noise reduction sub-circuit;
the first noise reduction sub-circuit is electrically connected with a fourth power supply terminal, the signal input terminal, the pull-up node, the first output terminal, the second output terminal, a first power supply terminal, and a third power supply terminal, respectively, and is configured to provide a signal of the first power supply terminal to the pull-up node and the second output terminal and provide a signal of the third power supply terminal to a pull-down node under control of signals of the signal input terminal, the pull-up node, and the fourth power supply terminal; and
the second noise reduction sub-circuit is electrically connected with a fifth power supply terminal, the signal input terminal, the pull-up node, the first output terminal, the second output terminal, the first power supply terminal, and the third power supply terminal, respectively, and is configured to provide the signal of the first power supply terminal to the pull-up node and the second output terminal and provide the signal of the third power supply terminal to the pull-down node under control of signals of the signal input terminal, the pull-up node, and the fifth power supply terminal.

16. The shift register according to claim 15, wherein the first noise reduction sub-circuit comprises a seventh transistor, an eighth transistor, a ninth transistor, a thirteenth transistor, a fourteenth transistor, and a fifteenth transistor, and the second noise reduction sub-circuit comprises a tenth transistor, an eleventh transistor, a twelfth transistor, a sixteenth transistor, a seventeenth transistor, and an eighteenth transistor;
a control electrode of the seventh transistor is electrically connected with the signal input terminal, a first electrode of the seventh transistor is electrically connected with a first pull-down node, and a second electrode of the seventh transistor is electrically connected with the first power supply terminal;
a control electrode of the eighth transistor is electrically connected with the pull-up node, a first electrode of the eighth transistor is electrically connected with the first pull-down node, and a second electrode of the eighth transistor is electrically connected with the first power supply terminal;
a control electrode and a first electrode of the ninth transistor are electrically connected with the fourth power supply terminal respectively, and a second electrode of the ninth transistor is electrically connected with the first pull-down node;
a control electrode of the tenth transistor is electrically connected with the signal input terminal, a first electrode of the tenth transistor is electrically connected with a second pull-down node, and a second electrode of the tenth transistor is electrically connected with the first power supply terminal;
a control electrode of the eleventh transistor is electrically connected with the pull-up node, a first electrode of the eleventh transistor is electrically connected with the second pull-down node, and a second electrode of the eleventh transistor is electrically connected with the first power supply terminal;
a control electrode and a first electrode of the twelfth transistor are respectively electrically connected with the fifth power supply terminal, and a second electrode of the twelfth transistor is electrically connected with the second pull-down node;
a control electrode of the thirteenth transistor is electrically connected with the first pull-down node, a first electrode of the thirteenth transistor is electrically connected with the pull-up node, and a second electrode of the thirteenth transistor is electrically connected with the first power supply terminal;
a control electrode of the fourteenth transistor is electrically connected with the first pull-down node, a first electrode of the fourteenth transistor is electrically connected with the first output terminal, and a second electrode of the fourteenth transistor is electrically connected with the third power supply terminal;
a control electrode of the fifteenth transistor is electrically connected with the first pull-down node, a first electrode of the fifteenth transistor is electrically connected with the second output terminal, and a second electrode of the fifteenth transistor is electrically connected with the first power supply terminal;
a control electrode of the sixteenth transistor is electrically connected with the second pull-down node, a first electrode of the sixteenth transistor is electrically connected with the pull-up node, and a second electrode of the sixteenth transistor is electrically connected with the first power supply terminal;
a control electrode of the seventeenth transistor is electrically connected with the second pull-down node, a first electrode of the seventeenth transistor is electrically connected with the first output terminal, and a second electrode of the seventeenth transistor is electrically connected with the third power supply terminal; and
a control electrode of the eighteenth transistor is electrically connected with the second pull-down node, a first electrode of the eighteenth transistor is electrically connected with the second output terminal, and a second electrode of the eighteenth transistor is electrically connected with the first power supply terminal.

17. The shift register according to claim 1, further comprising a first reset sub-circuit, a second reset sub-circuit, and a noise reduction sub-circuit; wherein the input sub-circuit comprises a first transistor, the output sub-circuit comprises a second transistor, a third transistor, and a capacitor, the first control sub-circuit comprises at least one of a nineteenth transistor and a twentieth transistor; the first reset sub-circuit comprises a fourth transistor, the second reset sub-circuit comprises a fifth transistor and a sixth transistor, and the noise reduction sub-circuit comprises a seventh transistor to an eighteenth transistor;
a control electrode of the first transistor is electrically connected with the signal input terminal, a first electrode of the first transistor is electrically connected with the signal input terminal or a second power supply terminal, and a second electrode of the first transistor is electrically connected with the pull-up node;
a control electrode of the second transistor is electrically connected with the pull-up node, a first electrode of the second transistor is electrically connected with the clock signal terminal, and a second electrode of the second transistor is electrically connected with the first output terminal;
a control electrode of the third transistor is electrically connected with the pull-up node, a first electrode of the third transistor is electrically connected with the clock signal terminal, and a second electrode of the third transistor is electrically connected with a second output terminal;
a first terminal of the capacitor is electrically connected with the pull-up node, and a second terminal of the capacitor is electrically connected with the first output terminal;
a control electrode of the fourth transistor is electrically connected with a total reset signal terminal, a first electrode of the fourth transistor is electrically connected with the pull-up node, and a second electrode of the fourth transistor is electrically connected with a first power supply terminal;
a control electrode of the fifth transistor is electrically connected with a first reset signal terminal, a first electrode of the fifth transistor is electrically connected with the pull-up node, and a second electrode of the fifth transistor is electrically connected with the first power supply terminal;
a control electrode of the sixth transistor is electrically connected with a second reset signal terminal, a first electrode of the sixth transistor is electrically connected with the first output terminal, and a second electrode of the sixth transistor is electrically connected with the first power supply terminal;
a control electrode of the seventh transistor is electrically connected with the signal input terminal, a first electrode of the seventh transistor is electrically connected with a first pull-down node, and a second electrode of the seventh transistor is electrically connected with the first power supply terminal;
a control electrode of the eighth transistor is electrically connected with the pull-up node, a first electrode of the eighth transistor is electrically connected with the first pull-down node, and a second electrode of the eighth transistor is electrically connected with the first power supply terminal;
a control electrode and a first electrode of the ninth transistor are electrically connected with a fourth power supply terminal respectively, and a second electrode of the ninth transistor is electrically connected with the first pull-down node;
a control electrode of the tenth transistor is electrically connected with the signal input terminal, a first electrode of the tenth transistor is electrically connected with a second pull-down node, and a second electrode of the tenth transistor is electrically connected with the first power supply terminal;
a control electrode of the eleventh transistor is electrically connected with the pull-up node, a first electrode of the eleventh transistor is electrically connected with the second pull-down node, and a second electrode of the eleventh transistor is electrically connected with the first power supply terminal;
a control electrode and a first electrode of the twelfth transistor are respectively electrically connected with a fifth power supply terminal, and a second electrode of the twelfth transistor is electrically connected with the second pull-down node;
a control electrode of the thirteenth transistor is electrically connected with the first pull-down node, a first electrode of the thirteenth transistor is electrically connected with the pull-up node, and a second electrode of the thirteenth transistor is electrically connected with the first power supply terminal;
a control electrode of the fourteenth transistor is electrically connected with the first pull-down node, a first electrode of the fourteenth transistor is electrically connected with the first output terminal, and a second electrode of the fourteenth transistor is electrically connected with a third power supply terminal;
a control electrode of the fifteenth transistor is electrically connected with the first pull-down node, a first electrode of the fifteenth transistor is electrically connected with the second output terminal, and a second electrode of the fifteenth transistor is electrically connected with the first power supply terminal;
a control electrode of the sixteenth transistor is electrically connected with the second pull-down node, a first electrode of the sixteenth transistor is electrically connected with the pull-up node, and a second electrode of the sixteenth transistor is electrically connected with the first power supply terminal;
a control electrode of the seventeenth transistor is electrically connected with the second pull-down node, a first electrode of the seventeenth transistor is electrically connected with the first output terminal, and a second electrode of the seventeenth transistor is electrically connected with the third power supply terminal;
a control electrode of the eighteenth transistor is electrically connected with the second pull-down node, a first electrode of the eighteenth transistor is electrically connected with the second output terminal, and a second electrode of the eighteenth transistor is electrically connected with the first power supply terminal;
a control electrode and a first electrode of the nineteenth transistor are respectively electrically connected with a first control signal terminal, and a second electrode of the nineteenth transistor is electrically connected with the signal input terminal; and
a control electrode and a first electrode of the twentieth transistor are respectively electrically connected with a second control signal terminal, and a second electrode of the twentieth transistor is electrically connected with the signal input terminal.

18. The shift register according to claim 1, further comprising a first reset sub-circuit, a second reset sub-circuit, and a noise reduction sub-circuit; wherein the input sub-circuit comprises a first transistor and a twenty-first transistor, the output sub-circuit comprises a second transistor, a third transistor, and a capacitor, the first control sub-circuit comprises at least one of a nineteenth transistor and a twentieth transistor; the first reset sub-circuit comprises a fourth transistor, the second reset sub-circuit comprises a fifth transistor and a sixth transistor, and the noise reduction sub-circuit comprises a seventh transistor to an eighteenth transistor;
a control electrode of the first transistor is electrically connected with the signal input terminal, a first electrode of the first transistor is electrically connected with the signal input terminal or a second power supply terminal, and a second electrode of the first transistor is electrically connected with a control node; and
a control electrode of the second transistor is electrically connected with the pull-up node, a first electrode of the second transistor is electrically connected with the clock signal terminal, and a second electrode of the second transistor is electrically connected with the first output terminal;
a control electrode of the third transistor is electrically connected with the pull-up node, a first electrode of the third transistor is electrically connected with the clock signal terminal, and a second electrode of the third transistor is electrically connected with a second output terminal;
a first terminal of the capacitor is electrically connected with the pull-up node, and a second terminal of the capacitor is electrically connected with the first output terminal;
a control electrode of the fourth transistor is electrically connected with a total reset signal terminal, a first electrode of the fourth transistor is electrically connected with the pull-up node, and a second electrode of the fourth transistor is electrically connected with a first power supply terminal;
a control electrode of the fifth transistor is electrically connected with a first reset signal terminal, a first electrode of the fifth transistor is electrically connected with the pull-up node, and a second electrode of the fifth transistor is electrically connected with the first power supply terminal;
a control electrode of the sixth transistor is electrically connected with a second reset signal terminal, a first electrode of the sixth transistor is electrically connected with the first output terminal, and a second electrode of the sixth transistor is electrically connected with the first power supply terminal;
a control electrode of the seventh transistor is electrically connected with the signal input terminal, a first electrode of the seventh transistor is electrically connected with a first pull-down node, and a second electrode of the seventh transistor is electrically connected with the first power supply terminal;
a control electrode of the eighth transistor is electrically connected with the pull-up node, a first electrode of the eighth transistor is electrically connected with the first pull-down node, and a second electrode of the eighth transistor is electrically connected with the first power supply terminal;
a control electrode and a first electrode of the ninth transistor are electrically connected with a fourth power supply terminal respectively, and a second electrode of the ninth transistor is electrically connected with the first pull-down node;
a control electrode of the tenth transistor is electrically connected with the signal input terminal, a first electrode of the tenth transistor is electrically connected with a second pull-down node, and a second electrode of the tenth transistor is electrically connected with the first power supply terminal;
a control electrode of the eleventh transistor is electrically connected with the pull-up node, a first electrode of the eleventh transistor is electrically connected with the second pull-down node, and a second electrode of the eleventh transistor is electrically connected with the first power supply terminal;
a control electrode and a first electrode of the twelfth transistor are respectively electrically connected with a fifth power supply terminal, and a second electrode of the twelfth transistor is electrically connected with the second pull-down node;
a control electrode of the thirteenth transistor is electrically connected with the first pull-down node, a first electrode of the thirteenth transistor is electrically connected with the pull-up node, and a second electrode of the thirteenth transistor is electrically connected with the first power supply terminal;
a control electrode of the fourteenth transistor is electrically connected with the first pull-down node, a first electrode of the fourteenth transistor is electrically connected with the first output terminal, and a second electrode of the fourteenth transistor is electrically connected with a third power supply terminal;
a control electrode of the fifteenth transistor is electrically connected with the first pull-down node, a first electrode of the fifteenth transistor is electrically connected with the second output terminal, and a second electrode of the fifteenth transistor is electrically connected with the first power supply terminal;
a control electrode of the sixteenth transistor is electrically connected with the second pull-down node, a first electrode of the sixteenth transistor is electrically connected with the pull-up node, and a second electrode of the sixteenth transistor is electrically connected with the first power supply terminal;
a control electrode of the seventeenth transistor is electrically connected with the second pull-down node, a first electrode of the seventeenth transistor is electrically connected with the first output terminal, and a second electrode of the seventeenth transistor is electrically connected with the third power supply terminal;
a control electrode of the eighteenth transistor is electrically connected with the second pull-down node, a first electrode of the eighteenth transistor is electrically connected with the second output terminal, and a second electrode of the eighteenth transistor is electrically connected with the first power supply terminal;
a control electrode and a first electrode of the nineteenth transistor are respectively electrically connected with a first control signal terminal, and a second electrode of the nineteenth transistor is electrically connected with the signal input terminal;
a control electrode and a first electrode of the twentieth transistor are respectively electrically connected with a second control signal terminal, and a second electrode of the twentieth transistor is electrically connected with the signal input terminal; and
a control electrode and a first electrode of the twenty-first transistor are respectively electrically connected with the control node, and a second electrode of the twenty-first transistor is electrically connected with the pull-up node.

19. A shift register, comprising an input sub-circuit, an output sub-circuit, and a second control sub-circuit; wherein
the input sub-circuit is electrically connected with a signal input terminal and a control node, respectively, and is configured to provide a signal to the control node under control of the signal input terminal;
the second control sub-circuit is electrically connected with the control node and a pull-up node, respectively, and is configured to provide a signal of the control node to the pull-up node under control of the signal of the control node; and
the output sub-circuit is electrically connected with a first output terminal, the pull-up node, and a clock signal terminal, respectively, and is configured to provide a signal of the clock signal terminal to the first output terminal under control of a signal of the pull-up node.

20. The shift register according to claim 19, further comprising a first reset sub-circuit, a second reset sub-circuit, and a noise reduction sub-circuit; wherein the input sub-circuit comprises a first transistor, the output sub-circuit comprises a second transistor, a third transistor, and a capacitor, the second control sub-circuit comprises a twenty-first transistor; the first reset sub-circuit comprises a fourth transistor, the second reset sub-circuit comprises a fifth transistor and a sixth transistor, and the noise reduction sub-circuit comprises a seventh transistor to an eighteenth transistor;
a control electrode of the first transistor is electrically connected with the signal input terminal, a first electrode of the first transistor is electrically connected with the signal input terminal or a second power supply terminal, and a second electrode of the first transistor is electrically connected with the control node;
a control electrode of the second transistor is electrically connected with the pull-up node, a first electrode of the second transistor is electrically connected with the clock signal terminal, and a second electrode of the second transistor is electrically connected with the first output terminal;
a control electrode of the third transistor is electrically connected with the pull-up node, a first electrode of the third transistor is electrically connected with the clock signal terminal, and a second electrode of the third transistor is electrically connected with a second output terminal;
a first terminal of the capacitor is electrically connected with the pull-up node, and a second terminal of the capacitor is electrically connected with the first output terminal;
a control electrode of the fourth transistor is electrically connected with a total reset signal terminal, a first electrode of the fourth transistor is electrically connected with the pull-up node, and a second electrode of the fourth transistor is electrically connected with a first power supply terminal;
a control electrode of the fifth transistor is electrically connected with a first reset signal terminal, a first electrode of the fifth transistor is electrically connected with the pull-up node, and a second electrode of the fifth transistor is electrically connected with the first power supply terminal;
a control electrode of the sixth transistor is electrically connected with a second reset signal terminal, a first electrode of the sixth transistor is electrically connected with the first output terminal, and a second electrode of the sixth transistor is electrically connected with the first power supply terminal;
a control electrode of the seventh transistor is electrically connected with the signal input terminal, a first electrode of the seventh transistor is electrically connected with a first pull-down node, and a second electrode of the seventh transistor is electrically connected with the first power supply terminal;
a control electrode of the eighth transistor is electrically connected with the pull-up node, a first electrode of the eighth transistor is electrically connected with the first pull-down node, and a second electrode of the eighth transistor is electrically connected with the first power supply terminal;
a control electrode and a first electrode of the ninth transistor are respectively electrically connected with a fourth power supply terminal, and a second electrode of the ninth transistor is electrically connected with the first pull-down node;
a control electrode of the tenth transistor is electrically connected with the signal input terminal, a first electrode of the tenth transistor is electrically connected with a second pull-down node, and a second electrode of the tenth transistor is electrically connected with the first power supply terminal;
a control electrode of the eleventh transistor is electrically connected with the pull-up node, a first electrode of the eleventh transistor is electrically connected with the second pull-down node, and a second electrode of the eleventh transistor is electrically connected with the first power supply terminal;
a control electrode and a first electrode of the twelfth transistor are respectively electrically connected with a fifth power supply terminal, and a second electrode of the twelfth transistor is electrically connected with the second pull-down node;
a control electrode of the thirteenth transistor is electrically connected with the first pull-down node, a first electrode of the thirteenth transistor is electrically connected with the pull-up node, and a second electrode of the thirteenth transistor is electrically connected with the first power supply terminal;
a control electrode of the fourteenth transistor is electrically connected with the first pull-down node, a first electrode of the fourteenth transistor is electrically connected with the first output terminal, and a second electrode of the fourteenth transistor is electrically connected with a third power supply terminal;
a control electrode of the fifteenth transistor is electrically connected with the first pull-down node, a first electrode of the fifteenth transistor is electrically connected with the second output terminal, and a second electrode of the fifteenth transistor is electrically connected with the first power supply terminal;
a control electrode of the sixteenth transistor is electrically connected with the second pull-down node, a first electrode of the sixteenth transistor is electrically connected with the pull-up node, and a second electrode of the sixteenth transistor is electrically connected with the first power supply terminal;
a control electrode of the seventeenth transistor is electrically connected with the second pull-down node, a first electrode of the seventeenth transistor is electrically connected with the first output terminal, and a second electrode of the seventeenth transistor is electrically connected with the third power supply terminal;
a control electrode of the eighteenth transistor is electrically connected with the second pull-down node, a first electrode of the eighteenth transistor is electrically connected with the second output terminal, and a second electrode of the eighteenth transistor is electrically connected with the first power supply terminal; and
a control electrode and a first electrode of the twenty-first transistor are respectively electrically connected with the control node, and a second electrode of the twenty-first transistor is electrically connected with the pull-up node.

21. A gate drive circuit, comprising a plurality of cascaded shift registers according to claim 1.

22. The gate drive circuit according to claim 21, wherein the gate drive circuit is disposed in a display apparatus, the display apparatus is provided with a gate line, and a shift register comprises an output sub-circuit; and
in a state in which the output sub-circuit comprises a first output terminal, a first output terminal of any stage of shift register is electrically connected with the gate line, a first output terminal of a current-stage shift register is electrically connected with a signal input terminal of a next-stage shift register, and the first output terminal of the current-stage shift register is electrically connected with a first reset signal terminal or a second reset signal terminal of a previous-stage shift register;
or,
wherein the gate drive circuit is disposed in a display apparatus, the display apparatus is provided with a gate line, and a shift register comprises an output sub-circuit; and
in a state in which the output sub-circuit comprises a first output terminal and a second output terminal, a first output terminal of any stage of shift register is electrically connected with the gate line, a second output terminal of a current-stage shift register is electrically connected with a signal input terminal of a next-stage shift register, and the second output terminal of the current-stage shift register is electrically connected with a first reset signal terminal or a second reset signal terminal of a previous-stage shift register.

23. (canceled)

24. A display apparatus, comprising a gate drive circuit according to claim 21.

25. A drive method of a shift register, configured to drive a shift register according to claim 1, wherein the method comprises:
providing, by an input sub-circuit, a signal to a pull-up node under control of a signal of a signal input terminal;
providing, by an output sub-circuit, a signal of a clock signal terminal to a first output terminal under control of a signal of the pull-up node; and
providing, by a control sub-circuit, a signal of a control signal terminal to the signal input terminal under control of the signal of the control signal terminal.

26. A drive method of a shift register, configured to drive a shift register according to claim 19, wherein the method comprises:
providing, by an input sub-circuit, a signal to a control node under control of a signal input terminal;
providing, by a second control sub-circuit, a signal of the control node to a pull-up node under control of the signal of the control node; and
providing, by an output sub-circuit, a signal of a clock signal terminal to a first output terminal under control of a signal of the pull-up node.
